(19) United States
(12) Patent Application Publication
(10) Pub. No.: US 2023/0025977 A1
(43) Pub. Date: Jan. 26, 2023

(54) SEMICONDUCTOR DEVICE AND METHOD OF MANUFACTURING SEMICONDUCTOR DEVICE

(71) Applicant: ROHM CO., LTD., Kyoto (JP)

(72) Inventors: Tadayuki YAMAZAKI, Kyoto (JP); Yushi SEKIGUCHI, Kyoto (JP)

(73) Assignee: ROHM CO., LTD., Kyoto (JP)

(21) Appl. No.: 17/868,765

(22) Filed: Jul. 19, 2022

(30) Foreign Application Priority Data
Jul. 26, 2021 (JP) 2021-121634

(51) Int. Cl. H01L 29/423; H01L 29/792; H01L 21/28; H01L 29/66

(52) U.S. Cl. CPC H01L 29/42344; H01L 29/792; H01L 29/40117; H01L 29/66833

(57) ABSTRACT

A semiconductor device includes a semiconductor layer including a first main surface, a first region of a first conduction type that is formed at a surface layer portion of the first main surface, a second region of a first conduction type that is formed at the surface layer portion of the first main surface and is separated from the first region in a first direction, a channel region of a second conduction type that is formed between the first region and the second region in the surface layer portion of the first main surface, a first gate electrode that is formed in a vicinity of the first region in the first main surface, faces the channel region, and includes a first side portion and a second side portion on an opposite side of the first side portion in the first direction.

### CROSS-REFERENCE TO RELATED APPLICATION

This application is based upon and claims the benefit of priority from Japanese Patent Application No. 2021-121634, filed on Jul. 26, 2021, the entire contents of which are incorporated herein by reference.

### TECHNICAL FIELD

The present disclosure relates to a semiconductor device and a method of manufacturing the semiconductor device.

### BACKGROUND

For example, related art discloses a semiconductor device including a nonvolatile memory. This semiconductor device includes a p-type semiconductor substrate, a gate electrode provided on the semiconductor substrate via a gate oxide film, and a transistor having a source region and a drain region, which are a pair of diffusion regions of n-type impurities, in a surface layer region of the semiconductor substrate and at positions sandwiching the gate electrode. A first resistance changing portion and a second resistance changing portion, which are regions having a lower n-type impurity concentration than those of the source region and the drain region, are formed in a region sandwiched between the source region and the drain region on one hand and a channel forming region on the other hand.

### SUMMARY

Some embodiments of the present disclosure provide a semiconductor device and a method of manufacturing the same, which are capable of increasing an amount of electric charges accumulated and improving write characteristics of a memory.

According to one embodiment of the present disclosure, a semiconductor device includes: a semiconductor layer including a first main surface; a first region of a first conduction type that is formed at a surface layer portion of the first main surface; a second region of a first conduction type that is formed at the surface layer portion of the first main surface and is separated from the first region in a first direction; a channel region of a second conduction type that is formed between the first region and the second region in the surface layer portion of the first main surface; a first gate electrode that is formed in a vicinity of the first region in the first main surface, faces the channel region, and includes a first side portion and a second side portion on an opposite side of the first side portion in the first direction; a first gate insulating film formed between the first gate electrode and the semiconductor layer; a first conductive layer that is formed in a vicinity of the second region in the first main surface, is separated from the first gate electrode across a space region having a predetermined width in the first direction, and includes a third side portion facing the first side portion of the first gate electrode and a fourth side portion on an opposite side of the third side portion; a first insulating film formed between the first conductive layer and the semiconductor layer, and a side wall structure that covers the first side portion of the first gate electrode, the third side portion of the first conductive layer, and the first main surface in the space region, and is formed in common to the first gate electrode and the first conductive layer.

### BRIEF DESCRIPTION OF DRAWINGS

The accompanying drawings, which are incorporated in and constitute a part of the specification, illustrate embodiments of the present disclosure.

FIG. 1 is a schematic perspective view of a semiconductor device according to an embodiment of the present disclosure.

FIG. 2 is a block diagram showing an overall configuration of the semiconductor device according to the embodiment of the present disclosure.

FIG. 3 is a schematic plan view showing a memory cell of FIG. 2 in an enlarged manner.

FIG. 4 is a cross-sectional view taken along IV-IV cross-section of FIG. 3.

FIG. 5A is an enlarged view surrounded by two-dot chain line V in FIG. 4 (first form).

FIG. 5B is an enlarged view surrounded by the two-dot chain line V in FIG. 4 (second form).

FIG. 6A is an electric circuit diagram for explaining a write operation (first pattern) of a memory transistor structure of FIG. 4.

FIG. 6B is an electric circuit diagram for explaining a read operation (first pattern) of the memory transistor structure of FIG. 4.

FIG. 7 is a diagram for comparing magnitudes of drain currents in an initial state and a memory state in the first pattern.

FIG. 8A is an electric circuit diagram for explaining a write operation (second pattern) of the memory transistor structure of FIG. 4.

FIG. 8B is an electric circuit diagram for explaining a read operation (second pattern) of the memory transistor structure of FIG. 4.

FIG. 9 is a diagram for comparing magnitudes of drain currents in an initial state and a memory state in the second pattern.

FIG. 10 is a schematic cross-sectional view of a semiconductor device according to another embodiment (Sample 1) of the present disclosure.

FIG. 11 is a schematic cross-sectional view of a semiconductor device according to another embodiment (Sample 2) of the present disclosure.

FIG. 12 is a diagram for comparing magnitudes of drain currents in an initial state and a memory state of Sample 1.

FIG. 13 is a diagram for comparing magnitudes of drain currents in the initial state and the memory state of Sample 1.

FIG. 14 is a diagram for comparing magnitudes of drain currents in an initial state and a memory state of Sample 2.

FIG. 15 is a diagram for comparing magnitudes of drain currents in the initial state and the memory state of Sample 2.

FIG. 16A is a view showing a part of a process of manufacturing the semiconductor device.

FIG. 16B is a view showing a next step of FIG. 16A.

FIG. 16C is a view showing a next step of FIG. 16B.

FIG. 16D is a view showing a next step of FIG. 16C.

FIG. 16E is a view showing a next step of FIG. 16D.

FIG. 16F is a view showing a next step of FIG. 16E.

FIG. 16G is a view showing a next step of FIG. 16F.

FIG. 16H is a view showing a next step of FIG. 16G.

FIG. 16I is a view showing a next step of FIG. 16H.

FIG. 16J is a view showing a next step of FIG. 16I.

FIG. 16K is a view showing a next step of FIG. 16J.

FIG. 16L is a view showing a next step of FIG. 16K.

FIG. 16M is a view showing a next step of FIG. 16L.

FIG. 16N is a view showing a next step of FIG. 16M.

FIG. 16O is a view showing a next step of FIG. 16N.

FIG. 16P is a view showing a next step of FIG. 16O.

FIG. 16Q is a view showing a next step of FIG. 16P.

FIG. 16R is a view showing a next step of FIG. 16Q.

FIG. 16S is a view showing a next step of FIG. 16R.

FIG. 17 is a schematic cross-sectional view of a semiconductor device according to another embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Embodiments of the present disclosure will be now described in detail with reference to the accompanying drawings.

### Planar Structure Of Memory Area 2

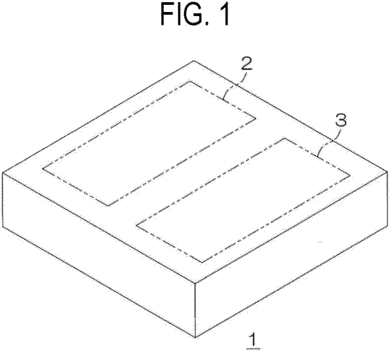

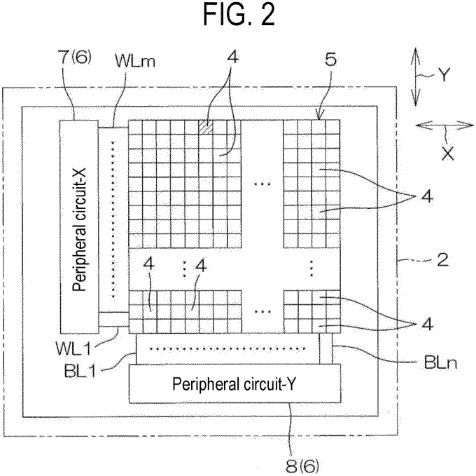

FIG. 1 is a schematic perspective view of a semiconductor device 1 according to an embodiment of the present disclosure. FIG. 2 is a block diagram showing an overall configuration of the semiconductor device 1 according to the embodiment of the present disclosure. In FIG. 2, rows and columns of some of matrix-shaped memory cells 4 are omitted due to a space limitation of the drawing, and omitted portions are indicated by “···.” Further, some of bit lines BL and word lines WL are omitted, and omitted portions are indicated by “---.”

Referring to FIG. 1, the semiconductor device 1 may be, for example, a chip-shaped LSI (Large Scale Integrated circuit). In this embodiment, the semiconductor device 1 is an analog LSI and may include a memory area 2 and a logic area 3, as one of components of the LSI circuit. For example, a memory element (OTP: One-Time Programmable) in which information (data) can be written only once but from which the information cannot be erased may be formed in the memory area 2. Further, for example, a memory element (MTP: Multi-Time Programmable) in which information (data) can be written a plurality of times may be formed in the memory area 2.

Referring to FIG. 2, the memory area 2 may include a memory array 5 including a plurality of memory cells 4 and a peripheral circuit 6. The memory cell 4 is a unit with hatching in FIG. 2, and the memory cells 4 are arranged in a form of a matrix (=mxn) to form the memory array 5. In this embodiment, in the memory cell 4, for example, m rows along a first direction X may be 1 to 1,024 rows, and n columns along a second direction Y may be 1 to 1,024 columns. The memory cell 4 may have a capacity of a kilobit order. Here, the kilobit order may be 1 K (kilo) bits or more and less than 1 M (mega) bits. The memory cell 4 may have a capacity of a megabit order and a capacity of a gigabit order.

The peripheral circuit 6 may include a first peripheral circuit 7 (peripheral circuit -X) and a second peripheral circuit 8 (peripheral circuit -Y). The first peripheral circuit 7 applies a predetermined gate voltage to a plurality of (m in this embodiment) word lines WL1 to WLm extending in parallel to each other in a row direction (X direction). The second peripheral circuit 8 applies a predetermined drain voltage Vds to a plurality of (n in this embodiment) bit lines BL1 to BLn extending in parallel to each other in a column direction (Y direction). Hereinafter, the word lines WL1 to WLm and the bit lines BL1 to BLn may be collectively referred to as a word line WL and a bit line BL, respectively. The word lines WL and the bit lines BL are provided with the same number as memory cells 4 in the row direction (first direction X) and the column direction (second direction Y).

An arithmetic element such as a CMOS transistor is formed in the logic area 3. The arithmetic element calculates and outputs information read from the memory cell 4 in the memory area 2.

### Structure of Memory Cell 4

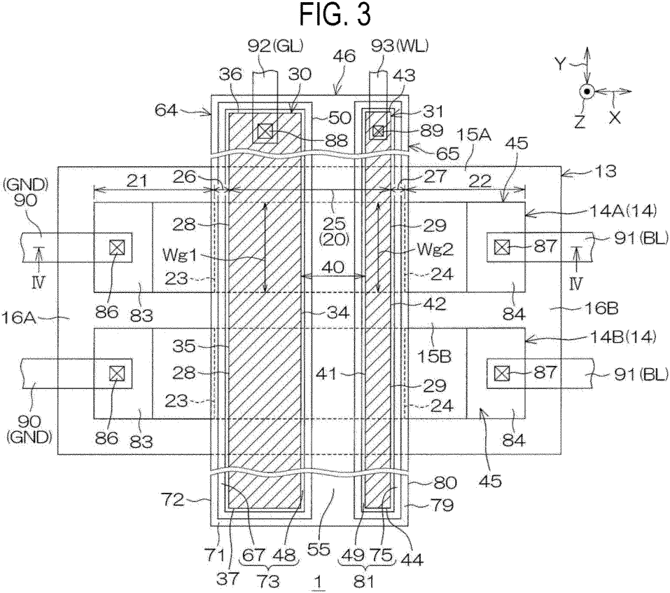

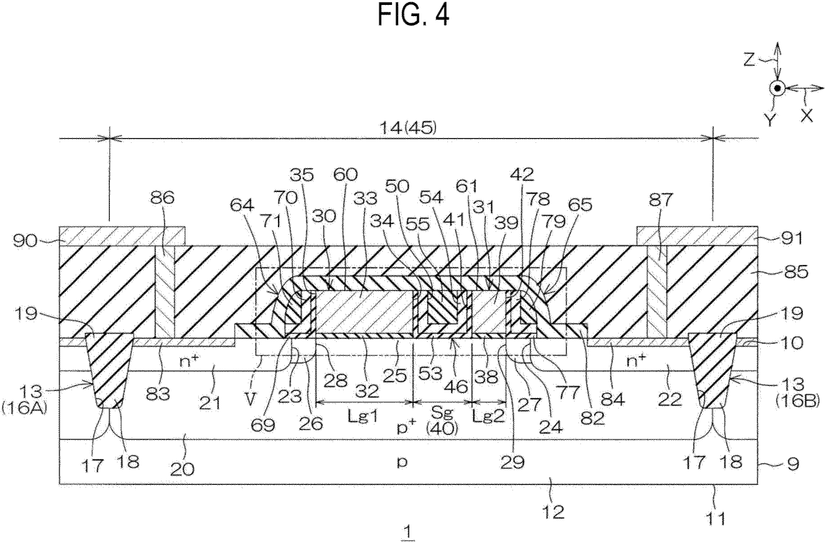

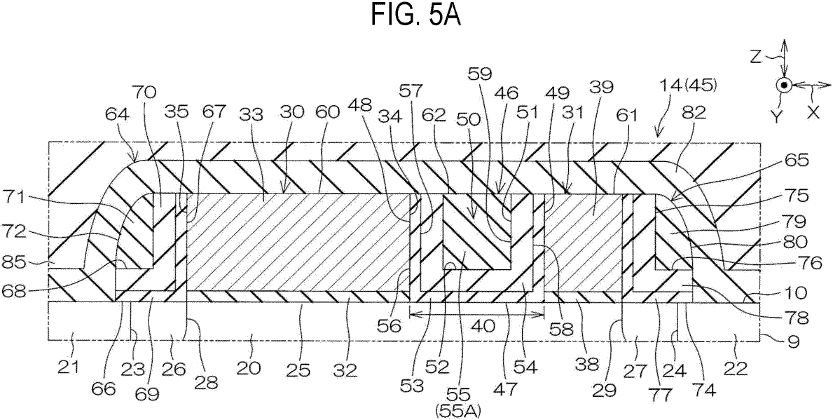

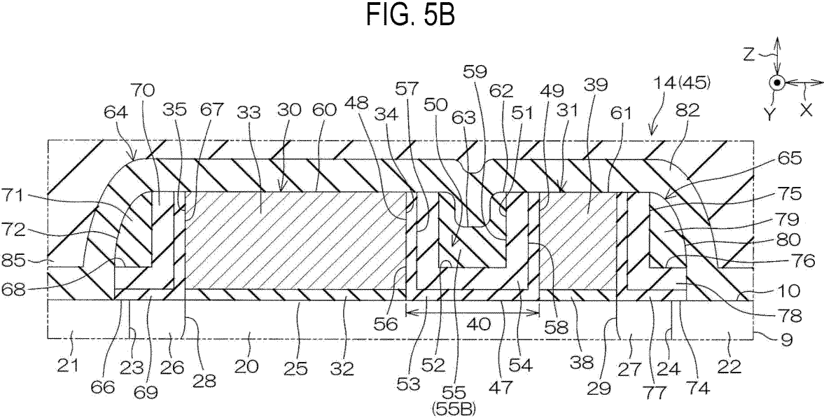

FIG. 3 is a schematic plan view showing the memory cell 4 of FIG. 2 in an enlarged manner. FIG. 4 is a cross-sectional view taken along IV-IV cross-section of FIG. 3. FIG. 5A is an enlarged view surrounded by two-dot chain line V in FIG. 4 (first form). FIG. 5B is an enlarged view surrounded by two-dot chain line V in FIG. 4 (second form). In FIGS. 3 to 5A and 5B , a flow direction of a current of a transistor is defined as the first direction X, and a direction which is orthogonal to the first direction X and is along a first main surface 10 of a semiconductor layer 9 is defined as the second direction Y. A third direction Z is a thickness direction of the semiconductor layer 9 and is defined as a direction orthogonal to the first direction X and the second direction Y. In FIG. 3, a first gate electrode 33 and a second gate electrode 39 are hatched for clarity.

The semiconductor device 1 includes the semiconductor layer 9. In this embodiment, the semiconductor layer 9 includes a Si semiconductor layer 9. The semiconductor layer 9 may be a semiconductor layer 9 made of another material (for example, silicon carbide (SiC) or the like). The semiconductor layer 9 may be referred to as a semiconductor chip, a semiconductor substrate, or an epitaxial layer. For example, the semiconductor layer 9 may be a single crystal chip to which no impurities are added. The semiconductor layer 9 may include the first main surface 10 and a second main surface 11 on the opposite side of the first main surface 10. The first main surface 10 may be referred to as an element forming surface, and the second main surface 11 may be referred to as a non-element forming surface. Further, the first main surface 10 may be referred to as a front surface of the semiconductor layer 9, and the second main surface 11 may be referred to as a back surface of the semiconductor layer 9.

A p-type (second conduction type) back gate region 12 is formed at a surface layer portion of the second main surface 11 of the semiconductor layer 9. The back gate region 12 is formed over the entire second main surface 11 of the semiconductor layer 9. A p-type impurity concentration in the back gate region 12 may be, for example, 1×10¹⁶ cm⁻³ or more and 1×10¹⁹ cm⁻³ or less. An element isolation portion 13 is formed at the first main surface 10 side of the semiconductor layer 9. In this embodiment, the element isolation portion 13 partitions a memory cell region 14 in which each memory cell 4 is arranged. The element isolation portion 13 insulates and separates adjacent memory cell regions 14. Each memory cell region 14 is surrounded by the element isolation portion 13. Two adjacent memory cell regions 14 are shown in FIG. 3. The memory cell region 14 of FIG. 3 may include a first memory cell region 14A and a second memory cell region 14B. The memory cells 4 arranged in the first memory cell region 14A and the second memory cell region 14B have the same transistor structure.

Referring to FIG. 3, the element isolation portion 13 surrounding each memory cell region 14 is formed in a rectangular shape including a pair of long side portions 15A and 15B along the first direction X and a pair of short side portions 16A and 16B along the second direction Y in a plan view. Each memory cell region 14 may be formed, for example, in a longitudinal rectangular shape in a plan view in the first direction X. The pair of long side portions 15A and 15B may be referred to as a first long side portion 15A and a second long side portion 15B, respectively. The pair of short side portions 16A and 16B may be referred to as a first short side portion 16A and a second short side portion 16B, respectively.

Referring to FIG. 4, the element isolation portion 13 may include an STI (Shallow Trench Isolation) structure. The element isolation portion 13 includes a trench 17 and an insulator 18 buried in the trench 17. The insulator 18 may include a protruding portion 19 protruding upward with respect to the first main surface 10 of the semiconductor layer 9. The element isolation portion 13 may include another element isolation structure such as a LOCOS oxide film or a DTI (Deep Trench Isolation) structure. Further, although not shown, the element isolation portion 13 may include a structure that isolates the memory area 2 and the logic area 3.

In each memory cell region 14, a p-type well region 20 is formed at the surface layer portion of the first main surface 10 of the semiconductor layer 9. The well region 20 is a p-type impurity region. A p-type impurity concentration in the well region 20 may exceed the p-type impurity concentration in the back gate region 12. For example, the p-type impurity concentration in the well region 20 may be 1×10¹⁶ cm⁻³ or more and 1×10¹⁹ cm⁻³ or less. A bottom of the well region 20 is electrically connected to the back gate region 12. In FIG. 4, in order to clarify a concentration difference between the well region 20 and the back gate region 12, the well region 20 is indicated by “p⁺” and the back gate region 12 is indicated by “p.” It should be noted here that “p⁺” and “p” do not indicate a specific concentration range.

The well region 20 is formed to be deeper than the trench 17 and partially covers a bottom wall of the trench 17 of both the long side portions 15A and 15B and the short side portions 16A and 16B of the element isolation portion 13. As a result, the well region 20 is formed over the entire memory cell region 14. Unlike a structure shown in FIG. 4, the well region 20 may be formed in a region at the first main surface 10 side with respect to the bottom wall of the trench 17. In this case, a boundary between the well region 20 and the back gate region 12 is located between the bottom wall of the trench 17 and the first main surface 10.

On a surface layer portion of the well region 20, an n-type (first conduction type) first region 21 and an n-type (first conduction type) second region 22 are formed at an interval in the first direction X. The first region 21 and the second region 22 are n-type impurity regions. The n-type impurity concentrations in the first region 21 and the second region 22 may be equal to each other. For example, the n-type impurity concentrations in the first region 21 and the second region 22 may be 1×10¹⁹ cm⁻³ or more and 1×10²² cm⁻³ or less. In FIG. 4, in order to clarify a concentration difference between the first region 21 and second region 22 on one hand and a first low-concentration impurity region 26 (to be described later) and second low-concentration impurity region 27 (to be described later) on the other hand, the first region 21 and the second region 22 are indicated by “n⁺.” It should be noted here that “n⁺” does not indicate a specific concentration range.

Referring to FIG. 3, a linear first boundary portion 23, which leads from the first long side portion 15A to the second long side portion 15B, is formed between the first region 21 and the well region 20. The first region 21 is formed in a rectangular shape (square shape) partitioned by the first boundary portion 23, the first long side portion 15A, the second long side portion 15B, and the first short side portion 16A in a plan view. The first region 21 extends from the first short side portion 16A of the element isolation portion 13 toward the second short side portion 16B of the element isolation portion 13 in the first direction X. The first region 21 includes an end portion on each of the first long side portion 15A and the second long side portion 15B in the second direction Y. As a result, the first region 21 is formed over the entire region from the first long side portion 15A to the second long side portion 15B in the second direction Y.

A linear second boundary portion 24, which leads from the first long side portion 15A to the second long side portion 15B is formed between the second region 22 and the well region 20. The second region 22 is formed in a rectangular shape (square shape) partitioned by the second boundary portion 24, the first long side portion 15A, the second long side portion 15B, and the second short side portion 16B in a plan view. The second region 22 extends from the second short side portion 16B of the element isolation portion 13 toward the first short side portion 16A of the element isolation portion 13 in the first direction X. The second region 22 includes an end portion on each of the first long side portion 15A and the second long side portion 15B in the second direction Y. As a result, the second region 22 is formed over the entire region from the first long side portion 15A to the second long side portion 15B in the second direction Y.

In the surface layer portion of the well region 20, a region between the first region 21 and the second region 22 is a channel region 25 in which an n-type channel is formed. The channel region 25 is formed by a part of a p-type portion of the well region 20. One of the first region 21 and the second region 22 may be a source region and the other may be a drain region. Which of the first region 21 and the second region 22 is the source region or the drain region may be defined by a direction in which electric charges flow at a time of writing of information (data). For example, at the time of writing of information, when the first region 21 is set as a reference voltage (for example, 0 V) and a positive voltage with respect to the reference voltage is applied to the second region 22, electrons induced in the p-type channel region 25 flow from the first region 21 toward the second region 22. In this case, the first region 21 is the source region and the second region 22 is the drain region. On the other hand, when the second region 22 is set to a reference voltage (for example, 0 V) and a positive voltage with respect to the reference voltage is applied to the first region 21, electrons induced in the p-type channel region 25 flow from the second region 22 toward the first region 21. In this case, the second region 22 is the source region and the first region 21 is the drain region.

The n-type (first conduction type) first low-concentration impurity region 26 and the n-type (first conduction type) second low-concentration impurity region 27 are formed at the surface layer of the well region 20. The first low-concentration impurity region 26 and the second low-concentration impurity region 27 are n-type impurity regions. The n-type impurity concentrations of the first low-concentration impurity region 26 and the second low-concentration impurity region 27 may be equal to each other. The n-type impurity concentrations of the first low-concentration impurity region 26 and the second low-concentration impurity region 27 are lower than the n-type impurity concentrations of the n-type impurity regions of the first region 21 and the second region 22. For example, the n-type impurity concentrations in the first low-concentration impurity region 26 and the second low-concentration impurity region 27 may be 1×10¹⁹ cm⁻³ or more and 1×10²² cm⁻³ or less.

Referring to FIG. 3, the first low-concentration impurity region 26 is formed between the first region 21 and the channel region 25. A linear third boundary portion 28, which leads from the first long side portion 15A to the second long side portion 15B, is formed between the first low-concentration impurity region 26 and the well region 20. The first low-concentration impurity region 26 is formed in a band shape from the first long side portion 15A to the second long side portion 15B. The first low-concentration impurity region 26 protrudes from a leading end portion (the first boundary portion 23) of the first region 21 toward the second region 22 in the first direction X. Referring to FIG. 4, a depth of the first low-concentration impurity region 26 from the first main surface 10 may be shallower than a depth of the first region 21 from the first main surface 10. The first low-concentration impurity region 26 may be referred to as a first LDD (Lightly Doped Drain) region.

Referring to FIG. 3, the second low-concentration impurity region 27 is formed between the second region 22 and the channel region 25. A linear fourth boundary portion 29, which leads from the first long side portion 15A to the second long side portion 15B, is formed between the second low-concentration impurity region 27 and the well region 20. The second low-concentration impurity region 27 is formed in a band shape from the first long side portion 15A to the second long side portion 15B. The second low-concentration impurity region 27 protrudes from a leading end portion (the second boundary portion 24) of the second region 22 toward the first region 21 in the first direction X. Referring to FIG. 4, a depth of the second low-concentration impurity region 27 from the first main surface 10 may be shallower than a depth of the second region 22 from the first main surface 10. The second low-concentration impurity region 27 may be referred to as a second LDD (Lightly Doped Drain) region.

Referring to FIG. 3, in the first direction X, the first region 21 and the first low-concentration impurity region 26 are exposed from the first main surface 10 on one side of the channel region 25, and the second region 22 and the second low-concentration impurity region 27 are exposed from the first main surface 10 on the other side of the channel region 25. A first planar gate structure 30 and a second planar gate structure 31 are formed on the first main surface 10 of the semiconductor layer 9. The first planar gate structure 30 and the second planar gate structure 31 are adjacent to each other at a distance in the first direction X.

In this embodiment, the first planar gate structure 30 is formed in a vicinity of the first region 21. Here, “the first planar gate structure 30 is formed in the vicinity of the first region 21” may be defined to mean that, with respect to a relative positional relationship between the first planar gate structure 30 and the second planar gate structure 31, the first planar gate structure 30 is arranged closer to the first region 21 than the second planar gate structure 31. Further, it may be defined that the first planar gate structure 30 is arranged at a position where a channel can be formed in the channel region 25. It may be defined that the first planar gate structure 30 is arranged so that an end portion (a second side portion 35 to be described later) of the first planar gate structure 30 in the first direction X is continuous or overlaps in the third direction Z with an end portion (the first boundary portion 23) of the first region 21 in the first direction X or an end portion (the third boundary portion 28) of the same conduction type region (in this embodiment, the first low-concentration impurity region 26) connected to the first region 21 in the first direction X. Although it can be expressed in various ways as described above, in this embodiment, the first planar gate structure 30 is arranged so that the first low-concentration impurity region 26 is formed in a self-aligned manner with respect to the end portion of the first planar gate structure 30 opposite to the second planar gate structure 31.

Referring to FIG. 3, the first planar gate structure 30 is formed to straddle the plurality of memory cell regions 14 and has a common structure in the plurality of memory cells 4. For example, in FIG. 3, the first planar gate structure 30 extends in a band shape along the second direction Y to cross the element isolation portion 13 between the memory cell regions 14 adjacent to each other in the second direction Y. Therefore, the first planar gate structure 30 is continuously formed to alternately cover the element isolation portion 13, the memory cell region 14, the element isolation portion 13, and the memory cell region 14 (the repetition thereof continues).

The first planar gate structure 30 includes a first gate insulating film 32 and a first gate electrode 33. The first gate insulating film 32 is formed on the first main surface 10 of the semiconductor layer 9. The first gate insulating film 32 may be formed of, for example, oxide of the semiconductor layer 9. Specifically, the first gate insulating film 32 is made of oxide formed into a film by oxidizing the surface layer portion of the first main surface 10. In this embodiment, the semiconductor layer 9 is a Si semiconductor layer, and the first gate insulating film 32 is a silicon oxide film (SiO₂) formed on the first main surface 10. The first gate insulating film 32 may have a thickness of 7 nm or more and 13 nm or less. The first gate insulating film 32 may have a constant thickness along the first main surface 10.

The first gate electrode 33 is formed on the first gate insulating film 32. The first gate electrode 33 faces the channel region 25 with the first gate insulating film 32 interposed therebetween. The first gate electrode 33 may be formed of, for example, conductive polysilicon. The first gate electrode 33 includes a first side portion 34 on the second planar gate structure 31 side and the second side portion 35 on an opposite side in the first direction X. Referring to FIG. 3, the first gate electrode 33 includes a first end portion 36 and a second end portion 37 facing each other in the second direction Y. The first gate electrode 33 may be formed in a band shape partitioned by the first side portion 34, the second side portion 35, the first end portion 36, and the second end portion 37 in a plan view. In FIG. 3, on both upper and lower sides of the memory cell region 14, a portion of the first gate electrode 33 extending in the second direction Y is omitted by dividing it by a wavy line.

Referring to FIG. 4, a first length Lg1 (first gate length) of the first gate electrode 33 in the first direction X may be, for example, 0.4 µm or more and 1 µm or less. The first gate length Lg1 may be defined by a distance between the first side portion 34 and the second side portion 35 of the first gate electrode 33. Referring to FIG. 3, in each memory cell region 14, a first width Wg1 (first gate width) of the first gate electrode 33 in the second direction Y may be, for example, 0.2 µm or more and 10 µm or less.

In this embodiment, the second planar gate structure 31 is formed in a vicinity of the second region 22. Here, “the second planar gate structure 31 is formed in the vicinity of the second region 22” may be defined to mean that, with respect to a relative positional relationship between the second planar gate structure 31 and the first planar gate structure 30, the second planar gate structure 31 is arranged closer to the second region 22 than the first planar gate structure 30. Further, it may be defined that the second planar gate structure 31 is arranged at a position where a channel can be formed in the channel region 25. It may be defined that the second planar gate structure 31 is arranged so that an end portion (a fourth side portion 42 to be described later) of the second planar gate structure 31 in the first direction X is continuous or overlaps in the third direction Z with an end portion (the second boundary portion 24) of the second region 22 in the first direction X or an end portion (the fourth boundary portion 29) of the same conduction type region (in this embodiment, the second low-concentration impurity region 27) connected to the second region 22 in the first direction X. Although it can be expressed in various ways as described above, in this embodiment, the second planar gate structure 31 is arranged so that the second low-concentration impurity region 27 is formed in a self-aligned manner with respect to the end portion of the second planar gate structure 31 opposite to the first planar gate structure 30.

Referring to FIG. 3, the second planar gate structure 31 is formed to straddle the plurality of memory cell regions 14 and has a common structure in the plurality of memory cells 4. For example, in FIG. 3, the second planar gate structure 31 extends in a band shape along the second direction Y to cross the element isolation portion 13 between the memory cell regions 14 adjacent to each other in the second direction Y. Therefore, the second planar gate structure 31 is continuously formed to alternately cover the element isolation portion 13, the memory cell region 14, the element isolation portion 13, and the memory cell region 14 (the repetition thereof continues).

The second planar gate structure 31 includes a second gate insulating film 38 (first insulating film) and a second gate electrode 39 (first conductive layer). The second gate insulating film 38 is formed on the first main surface 10 of the semiconductor layer 9. The second gate insulating film 38 may be formed of, for example, oxide of the semiconductor layer 9. Specifically, the second gate insulating film 38 is made of oxide formed into a film by oxidizing the surface layer portion of the first main surface 10. In this embodiment, the semiconductor layer 9 is a Si semiconductor layer, and the second gate insulating film 38 is a silicon oxide film (SiO₂) formed on the first main surface 10. The second gate insulating film 38 may have the same thickness as the first gate insulating film 32. The second gate insulating film 38 may have a thickness of 7 nm or more and 13 nm or less. The second gate insulating film 38 may have a constant thickness along the first main surface 10.

The second gate electrode 39 is formed on the second gate insulating film 38. The second gate electrode 39 faces the channel region 25 with the second gate insulating film 38 interposed therebetween. The second gate electrode 39 may be formed of, for example, conductive polysilicon. The second gate electrode 39 is separated from the first gate electrode 33 across a space region 40 in the first direction X. The second gate electrode 39 includes a third side portion 41 on the first planar gate structure 30 side and the fourth side portion 42 on an opposite side in the first direction X. The third side portion 41 of the second gate electrode 39 faces the first side portion 34 of the first gate electrode 33 in the first direction X. Referring to FIG. 3, the second gate electrode 39 includes a third end portion 43 and a fourth end portion 44 facing each other in the second direction Y. The second gate electrode 39 may be formed in a band shape partitioned by the third side portion 41, the fourth side portion 42, the third end portion 43, and the fourth end portion 44 in a plan view. In FIG. 3, on both upper and lower sides of the memory cell region 14, a portion of the second gate electrode 39 extending in the second direction Y is omitted by dividing it by a wavy line.

Referring to FIG. 4, a second length Lg2 (second gate length) of the second gate electrode 39 in the first direction X may be, for example, 0.1 µm or more and 0.4 µm or less. That is, the first gate length Lg1 may be larger than the second gate length Lg2. The second gate length Lg2 may be defined by a distance between the third side portion 41 and the fourth side portion 42 of the second gate electrode 39. Referring to FIG. 3, in each memory cell region 14, a second width Wg2 (second gate width) of the second gate electrode 39 in the second direction Y may be the same as the first width Wg1. The second width Wg2 may be, for example, 0.1 µm or more and 10 µm or less.

Referring to FIG. 4, the space region 40 is formed with a predetermined width Sg along the second direction Y. The width Sg (gate space, third length) of the space region 40 may be, for example, 0.1 µm or more and 0.2 µm or less. The gate space Sg may be defined by a distance between the first side portion 34 of the first gate electrode 33 and the third side portion 41 of the second gate electrode 39. In this way, in each memory cell 4, the first planar gate structure 30 and the second planar gate structure 31 are adjacent to each other between the first region 21 and the second region 22 (between a source and a drain) via the space region 40. As a result, the memory cell 4 includes a single memory transistor structure 45 including a pair of gate structures of the first planar gate structure 30 and the second planar gate structure 31. In this embodiment, the single memory transistor structure 45 may be defined as a transistor including a pair of first region 21 and second region 22 and a pair of first planar gate structure 30 and second planar gate structure 31 formed adjacent to each other. That is, in the single memory transistor structure 45, a pair of first gate electrode 33 and second gate electrode 39 that are electrically and physically independent of each other may be formed between the source and the drain.

Each memory cell 4 includes an integrated side wall structure 46 as the same side wall structure as the first planar gate structure 30 and the second planar gate structure 31. In each memory cell 4, the integrated side wall structure 46 is formed to integrally cover the first side portion 34 of the first gate electrode 33, the third side portion 41 of the second gate electrode 39, and the first main surface 10 in the space region 40. In this embodiment, the integrated side wall structure 46 is a portion where information is written in the memory cell 4, and may be referred to as an integrated memory structure. Further, since the integrated side wall structure 46 is the same structure as the first planar gate structure 30 and the second planar gate structure 31, it may be referred to as a common side wall structure or a common memory structure.

Referring to FIGS. 5A and 5B, the integrated side wall structure 46 includes a base portion 47 formed on the first main surface 10, a first wall portion 48 erected from the base portion 47 along the first side portion 34 of the first gate electrode 33, and a second wall portion 49 erected from the base portion 47 along the third side portion 41 of the second gate electrode 39. The base portion 47, the first wall portion 48, and the second wall portion 49 are orthogonally connected to each other at lower portions of the first side portion 34 of the first gate electrode 33 and the third side portion 41 of the second gate electrode 39. As a result, a recess 50 (space) partitioned by the base portion 47, the first wall portion 48, and the second wall portion 49 is formed between the first gate electrode 33 and the second gate electrode 39.

Referring to FIG. 3, the recess 50 is formed in a band shape extending along the second direction Y. The band-shaped recess 50 is partitioned by the base portion 47, the first wall portion 48, and the second wall portion 49, which are made of an insulating material, and may be referred to as a trench. Referring to FIGS. 5A and 5B, the trench (the recess 50) may be referred to as an insulating trench 50 including a side portion 51 made of an insulating material and a bottom portion 52 made of an insulating material.

Referring to FIGS. 5A and 5B, the integrated side wall structure 46 includes a memory insulating film 53 (lower layer film), a charge storage film 54 (upper layer film), and an insulating spacer 55. A laminated film of the memory insulating film 53 and the charge storage film 54 forms the above-mentioned recess 50. The memory insulating film 53 is formed in a form of a film including a first surface 56 and a second surface 57 along the first side portion 34 of the first gate electrode 33, the third side portion 41 of the second gate electrode 39, and the first main surface 10 in the space region 40. The first surface 56 of the memory insulating film 53 may be a surface in contact with the first side portion 34, the third side portion 41, and the first main surface 10, and the second surface 57 may be a surface on the opposite side of the first surface 56. Therefore, the memory insulating film 53 may have a constant thickness along the first side portion 34, the first main surface 10, and the third side portion 41 (a constant distance between the first surface 56 and the second surface 57).

The memory insulating film 53 may be formed of oxide of the semiconductor layer 9, the first gate electrode 33, and the second gate electrode 39. Specifically, the memory insulating film 53 is made of oxide formed in a form of a film by oxidizing the surface layer portion of the first main surface 10, the first side portion 34 of the first gate electrode 33, and the third side portion 41 of the second gate electrode 39. In this embodiment, the semiconductor layer 9 is a Si semiconductor layer, the first gate electrode 33 and the second gate electrode 39 are polysilicon, and the memory insulating film 53 is a silicon oxide film (SiO₂ film) in contact with the first main surface 10, the first side portion 34 of the first gate electrode 33, and the third side portion 41 of the second gate electrode 39. The memory insulating film 53 may have a thickness of 5 nm or more and 10 nm or less. The memory insulating film 53 is preferably thinner than a gate insulating film 104.

The charge storage film 54 is formed in a form of a film including a first surface 58 and a second surface 59 along the first side portion 34 of the first gate electrode 33, the third side portion 41 of the second gate electrode 39, and the first main surface 10 in the space region 40. The first surface 58 of the charge storage film 54 may be a surface in contact with the memory insulating film 53, and the second surface 59 may be a surface on the opposite side of the first surface 58. Therefore, the charge storage film 54 may have a constant thickness along the first side portion 34, the first main surface 10, and the third side portion 41 (a constant distance between the first surface 58 and the second surface 59).

The charge storage film 54 is made of an insulating material different from that of the memory insulating film 53 and is formed of, for example, a silicon nitride film (SiN film). The charge storage film 54 is laminated on the memory insulating film 53. The charge storage film 54 may have a thickness larger than that of the memory insulating film 53. The thickness of the charge storage film 54 may be, for example, 10 nm or more and 50 nm or less. The insulating spacer 55 is formed in the recess 50 and is adjacent to the charge storage film 54. The insulating spacer 55 is buried in the recess 50. As shown in FIG. 5A, as a first form, the insulating spacer 55 may completely backfill the recess 50 to have an upper surface 62 flush with upper portions (upper surfaces 60 and 61) of the first gate electrode 33 and the second gate electrode 39. In this case, the insulating spacer 55 may be referred to as a buried insulator 55A that is buried in the recess 50 to cover the side portion 51 and the bottom portion 52 (the surface of the charge storage film 54) of the recess 50.

Further, as shown in FIG. 5B, as a second form, the insulating spacer 55 may backfill a portion of the recess 50 to include an upper surface 62 on which a recess 63 recessed with respect to the upper portions (upper surfaces 60 and 61) of the first gate electrode 33 and the second gate electrode 39 is formed. In this case, the insulating spacer 55 may be referred to as an internal insulating film 55B which is formed in the recess 50 to cover the side portion 51 and the bottom portion 52 (the surface of the charge storage film 54) of the recess 50. Further, since the buried insulator 55A and the internal insulating film 55B cover and protect the charge storage film 54 in the recess 50, they may be referred to as a protective insulator and a protective insulating film, respectively.

The memory cell 4 further includes a first side wall structure 64 formed on the second side portion 35 of the first planar gate structure 30 and a second side wall structure 65 formed on the fourth side portion 42 of the second planar gate structure 31. Referring to FIGS. 5A and 5B, the first side wall structure 64 includes a base portion 66 formed on the first main surface 10 and a wall portion 67 erected along the second side portion 35 of the first gate electrode 33 from the base portion 66. The base portion 66 and the wall portion 67 are orthogonally connected to each other at a lower portion of the second side portion 35 of the first gate electrode 33 to form an L-shaped structure in a cross-sectional view. As a result, in the first side wall structure 64, a first recess 68, which is opened toward an outside of the first direction X and an upper side of the third direction Z with respect to the first gate electrode 33, is formed between a side surface of the base portion 66 and an upper surface of the wall portion 67.

Referring to FIGS. 5A and 5B, the first side wall structure 64 includes a first lower layer film 69, a first upper layer film 70, and a first insulating spacer 71. The first lower layer film 69 and the first upper layer film 70 form the above-mentioned L-shaped structure in a cross-sectional view, each of which is formed in an L-shape in a cross-sectional view. The first lower layer film 69 may be formed of oxides of the semiconductor layer 9 and the first gate electrode 33. Specifically, the first lower layer film 69 is made of oxide formed in a form of a film by oxidizing the surface layer portion of the first main surface 10 and the second side portion 35 of the first gate electrode 33. In this embodiment, the semiconductor layer 9 is a Si semiconductor layer, the first gate electrode 33 is polysilicon, and the first lower layer film 69 is a silicon oxide film (SiO₂ film) in contact with the first main surface 10 and the second side portion 35 of the first gate electrode 33. The first lower layer film 69 may have a thickness of 5 nm or more and 10 nm or less. The first lower layer film 69 is preferably thinner than the first gate insulating film 32.

The first upper layer film 70 is made of an insulating material different from that of the first lower layer film 69 and is formed of, for example, a silicon nitride film (SiN film). The first upper layer film 70 is laminated on the first lower layer film 69 and is formed in an L-shape along an L-shaped surface of the first lower layer film 69 in a cross-sectional view. The first upper layer film 70 may have a thickness larger than that of the first lower layer film 69. The thickness of the first upper layer film 70 may, for example, 10 nm or more and 50 nm or less.

The first insulating spacer 71 is formed in the first recess 68 and is adjacent to the first upper layer film 70. The first insulating spacer 71 is made of, for example, silicon oxide. The first insulating spacer 71 faces the first lower layer film 69 with the first upper layer film 70 interposed therebetween. Further, the first insulating spacer 71 is in contact with both the base portion 66 and the wall portion 67 of the first side wall structure 64. An outer surface 72 of the first insulating spacer 71 may include a curved portion protruding outward in the first direction X of the first gate electrode 33.

Referring to FIG. 3, the integrated side wall structure 46 and the first side wall structure 64 are continuous at the first end portion 36 and the second end portion 37 of the first gate electrode 33. The first wall portion 48 of the integrated side wall structure 46 and the wall portion 67 of the first side wall structure 64 are continuous around the first gate electrode 33, so that a first annular wall portion 73 may be formed in an annular shape, as a whole, in a plan view.

Referring to FIGS. 5A and 5B, the second side wall structure 65 includes a base portion 74 formed on the first main surface 10 and a wall portion 75 erected along the fourth side portion 42 of the second gate electrode 39 from the base portion 74. The base portion 74 and the wall portion 75 are orthogonally connected to each other at a lower portion of the fourth side portion 42 of the second gate electrode 39 to form an L-shaped structure in a cross-sectional view. As a result, in the second side wall structure 65, a second recess 76 that is opened toward an outside of the first direction X and an upper side of the third direction Z with respect to the second gate electrode 39 is formed between a side surface of the base portion 74 and an upper surface of the wall portion 75.

Referring to FIGS. 5A and 5B, the second side wall structure 65 includes a second lower layer film 77, a second upper layer film 78, and a second insulating spacer 79. The second lower layer film 77 and the second upper layer film 78 form the above-mentioned L-shaped structure in a cross-sectional view, each of which is formed in an L-shape in a cross-sectional view. The second lower layer film 77 may be formed of oxide of the semiconductor layer 9 and the second gate electrode 39. Specifically, the second lower layer film 77 is made of oxide formed in a form of a film by oxidizing the surface layer portion of the first main surface 10 and the fourth side portion 42 of the second gate electrode 39. In this embodiment, the semiconductor layer 9 is a Si semiconductor layer, the second gate electrode 39 is polysilicon, and the second lower layer film 77 is a silicon oxide film (SiO₂ film) in contact with the first main surface 10 and the fourth side portion 42 of the second gate electrode 39. The second lower layer film 77 may have a thickness of 5 nm or more and 10 nm or less. The second lower layer film 77 is preferably thinner than the first gate insulating film 32.

The second upper layer film 78 is made of an insulating material different from that of the second lower layer film 77 and is formed of, for example, a silicon nitride film (SiN film). The second upper layer film 78 is laminated on the second lower layer film 77 and is formed in an L-shape along an L-shaped surface of the second lower layer film 77 in a cross-sectional view. The second upper layer film 78 may have a thickness larger than that of the second lower layer film 77. The thickness of the second upper layer film 78 may, for example, 10 nm or more and 50 nm or less.

The second insulating spacer 79 is formed in the second recess 76 and is adjacent to the second upper layer film 78. The second insulating spacer 79 is made of, for example, silicon oxide. The second insulating spacer 79 faces the second lower layer film 77 with the second upper layer film 78 interposed therebetween. Further, the second insulating spacer 79 is in contact with both the base portion 74 and the wall portion 75 of the second side wall structure 65. An outer surface 80 of the second insulating spacer 79 may include a curved portion protruding outward in the first direction X of the second gate electrode 39.

Referring to FIG. 3, the integrated side wall structure 46 and the second side wall structure 65 are continuous at the third end portion 43 and the fourth end portion 44 of the second gate electrode 39. The second wall portion 49 of the integrated side wall structure 46 and the wall portion 75 of the second side wall structure 65 are continuous around the second gate electrode 39, so that a second annular wall portion 81 may be formed in an annular shape, as a whole, in a plan view.

The first region 21 is formed in a self-aligned manner with respect to the first side wall structure 64. Therefore, the first boundary portion 23 between the first region 21 and the channel region 25 substantially coincides with an outer surface of the first side wall structure 64 (the outer surface 72 of the first insulating spacer 71) in a plan view. The first boundary portion 23 between the first region 21 and the channel region 25 may be located slightly closer to the first planar gate structure 30 than the outer surface of the first side wall structure 64. The first low-concentration impurity region 26 is formed in a self-aligned manner with respect to the second side portion 35 of the first gate electrode 33. Therefore, the third boundary portion 28 between the first low-concentration impurity region 26 and the channel region 25 substantially coincides with the second side portion 35 of the first gate electrode 33 in a plan view. The first low-concentration impurity region 26 may be covered with the first side wall structure 64 in the first main surface 10.

The second region 22 is formed in a self-aligned manner with respect to the second side wall structure 65. Therefore, the second boundary portion 24 between the second region 22 and the channel region 25 substantially coincides with an outer surface of the second side wall structure 65 (the outer surface 80 of the second insulating spacer 79) in a plan view. The second boundary portion 24 between the second region 22 and the channel region 25 may be located slightly closer to the second planar gate structure 31 than the outer surface of the second side wall structure 65. The second low-concentration impurity region 27 is formed in a self-aligned manner with respect to the fourth side portion 42 of the second gate electrode 39. Therefore, the fourth boundary portion 29 between the second low-concentration impurity region 27 and the channel region 25 substantially coincides with the fourth side portion 42 of the second gate electrode 39 in a plan view. The second low-concentration impurity region 27 may be covered with the second side wall structure 65 in the first main surface 10.

Each memory cell 4 further includes a coating insulating film 82 that integrally covers a portion of the first region 21, the first planar gate structure 30, the first side wall structure 64, the integrated side wall structure 46, the second planar gate structure 31, the second side wall structure 65, and a portion of the second region 22. The coating insulating film 82 is formed of, for example, a silicon oxide film (SiO₂ film). The coating insulating film 82 may be referred to as a salicide block film because it prevents silicidization of the first gate electrode 33 and the second gate electrode 39.

A first silicide film 83 and a second silicide film 84 are formed at portions exposed from the coating insulating film 82 in the first region 21 and the second region 22, respectively. The first silicide film 83 and the second silicide film 84 may each contain, for example, at least one of TiSi, TiSi₂, NiSi, CoSi, CoSi₂, MoSi₂, and WSi₂. Referring to FIG. 3, the first silicide film 83 and the second silicide film 84 are formed in a square shape in a plan view to extend from the first long side portion 15A of the element isolation portion 13 to the second long side portion 15B of the element isolation portion 13.

Referring to FIG. 4, an interlayer insulating film 85 is formed over the first main surface 10. The interlayer insulating film 85 may include at least one of a silicon oxide film (SiO₂ film) and a silicon nitride film (SiN film). The interlayer insulating film 85 may include a single-layer structure formed of a silicon oxide film or a silicon nitride film. The interlayer insulating film 85 may include a laminated structure in which one or more silicon oxide films and one or more silicon nitride films are laminated in any order.

A first contact 86 and a second contact 87 are formed in the interlayer insulating film 85. Referring to FIG. 4, the first contact 86 and the second contact 87 penetrate the interlayer insulating film 85 in the thickness direction. The first contact 86 is mechanically and electrically connected to the first silicide film 83 of the first region 21 on an outside of the coating insulating film 82. The second contact 87 is mechanically and electrically connected to the second silicide film 84 of the second region 22 on the outside of the coating insulating film 82. The first contact 86 and the second contact 87 may be formed of, for example, at least one of copper and tungsten.

A first gate contact 88 and a second gate contact 89 are further formed in the interlayer insulating film 85. Although not shown in FIG. 4, the first gate contact 88 and the second gate contact 89 penetrate the interlayer insulating film 85 in the thickness direction, similarly to the first contact 86 and the second contact 87. The first gate contact 88 is mechanically and electrically connected to the first gate electrode 33 on the outside of the memory cell region 14. The second gate contact 89 is mechanically and electrically connected to the second gate electrode 39 on the outside of the memory cell region 14. The first gate contact 88 and the second gate contact 89 may be formed of, for example, at least one of copper and tungsten.

A first wiring 90, a second wiring 91, a first gate wiring 92, and a second gate wiring 93 are formed on the interlayer insulating film 85. The first wiring 90, the second wiring 91, the first gate wiring 92, and the second gate wiring 93 may be, for example, aluminum wirings. The first wiring 90 is electrically connected to the first region 21 via the first contact 86. The second wiring 91 is electrically connected to the second region 22 via the second contact 87. One of the first wiring 90 and the second wiring 91 may be the bit line BL in FIG. 2, and the other may be connected to the ground (GND) potential. One of the first wiring 90 and the second wiring 91 may be referred to as a source wiring and the other may be referred to as a drain wiring, corresponding to a function of the source/drain of the transistor of the memory cell 4. A ground side may be the source wiring and a bit line BL side may be the drain wiring. FIG. 3 shows a case where the first wiring 90 is the source wiring (GND) and the second wiring 91 is the drain wiring (bit line BL). The source wiring may be a common wiring in the plurality of memory cells 4.

The first gate wiring 92 is electrically connected to the first gate electrode 33 via the first gate contact 88. The second gate wiring 93 is electrically connected to the second gate electrode 39 via the second gate contact 89. One of the first gate wiring 92 and the second gate wiring 93 may be the word line WL in FIG. 2 and the other may be a gate line GL (omitted in FIG. 2). In this embodiment, a wiring connected to a selection gate electrode 95 to be described later may be the word line WL, and a wiring connected to a storage gate electrode 94 may be the gate line GL. FIG. 3 shows a case where the first gate wiring 92 is the gate line GL and the second gate wiring 93 is the word line WL.

### Operation of Memory Cell 4

Next, a write operation and a read operation of the memory cell 4 including the structure of FIG. 4 will be described, and write characteristics will be evaluated.

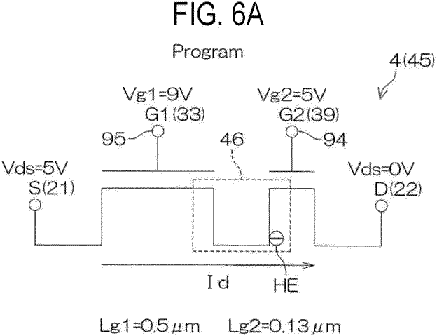

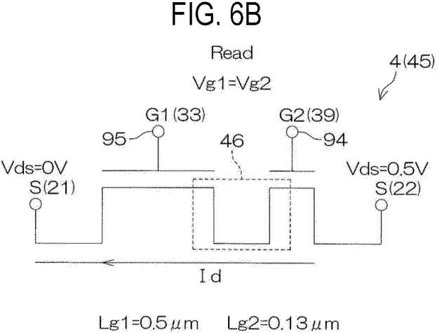

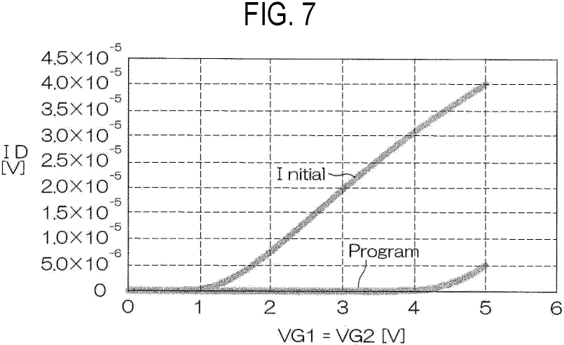

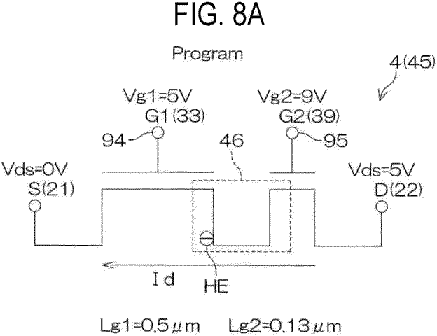

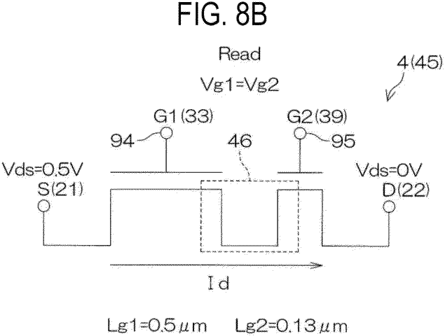

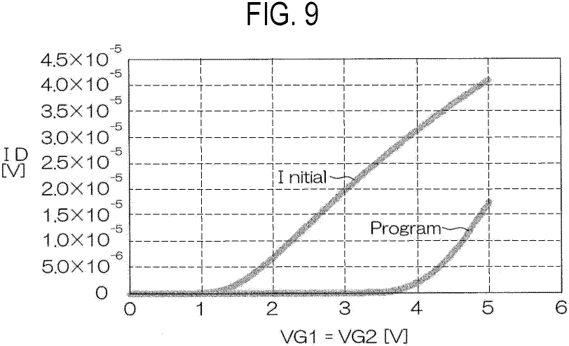

FIGS. 6A and 6B are electric circuit diagrams for explaining the write operation and the read operation of the memory transistor structure 45 of FIG. 4, respectively (first pattern). FIG. 7 is a diagram for comparing magnitudes of drain currents in an initial state and a memory state in the first pattern. FIGS. 8A and 8B are electric circuit diagrams for explaining the write operation and the read operation of the memory transistor structure 45 of FIG. 4, respectively (second pattern). FIG. 9 is a diagram for comparing magnitudes of drain currents in an initial state and a memory state in the second pattern.

In FIGS. 6A and 6B and FIGS. 8A and 8B, “D” indicates the drain of the memory transistor structure 45, and “S” indicates the source of the memory transistor structure 45. Numbers in parentheses in the source S and the drain D correspond to reference numerals in FIG. 4. For example, in FIGS. 6A and 6B, they are shown as D(21) and S(22). This means that in FIG. 4, the first region 21 is the drain D and the second region 22 is the source S. Conversely, in FIGS. 8A and 8B, it means that in FIG. 4, the second region 22 is the drain D and the first region 21 is the source S. That is, in the memory transistor structure 45 of FIG. 4, depending on a polarity of a voltage applied between the first region 21 and the second region 22, the first region 21 may be the drain region (the second region 22 is the source region) (the first pattern of FIGS. 6A and 6B), and the first region 21 may be the source region (the second region 22 is the drain region) (the second pattern of FIGS. 8A and 8B).

Further, “G1” and “G2” indicate the first gate electrode 33 and the second gate electrode 39, respectively. “Lg1” and “Lg2” indicate the first gate length and the second gate length, respectively, and specific lengths used in this evaluation are also shown with numbers. In FIGS. 7 and 9, a horizontal axis represents magnitudes of a gate voltage Vg1 and a gate voltage Vg2 (Vg1=Vg2), and a vertical axis represents a magnitude of a drain current Id.

First, the first pattern in which the first region 21 of FIG. 4 is the drain D and the second region 22 of FIG. 4 is the source S will be described. As shown in FIG. 6A, the write operation (Program) of the first pattern is achieved by injecting electrons (hot electron HE), which are generated by impact ionization in the vicinity of the second region 22 (the source S), into the integrated side wall structure 46. Specifically, at a time of the write operation, a reference voltage (for example, Vds=0 V) is applied to the second region 22 via the second wiring 91, and a positive voltage (for example, Vds=5 V) is applied to the first region 21 via the first wiring 90. At this time, of the first gate electrode 33 and the second gate electrode 39, the second gate electrode 39 on a side closer to the source S is used as the storage gate electrode 94, and the first gate electrode 33 on a side closer to the drain D is used as the selection gate electrode 95. The gate voltage Vg1 higher than the gate voltage (applied voltage) Vg2 of the storage gate electrode 94 is applied to the selection gate electrode 95. For example, the gate voltage of the selection gate electrode 95 may be Vg1=9 V, and the gate voltage of the storage gate electrode 94 may be Vg2=5 V.

As a result, electrons are induced in the vicinity of the first gate electrode 33 and the second gate electrode 39 of the channel region 25 to form a channel, and the drain current Id flows between the source and the drain from the first region 21 toward the second region 22. In the vicinity of the second region 22 (the source S), hot electrons HE are generated by impact ionization caused by electric field concentration. Then, the hot electrons HE are injected into the integrated side wall structure 46 (particularly, the charge storage film 54). As a result, information (data) is written in the integrated side wall structure 46. The gate voltages Vg1 and Vg2 and the drain-source voltage Vds in the write operation are not limited to above values, and can be appropriately changed according to specifications of the semiconductor device 1.

Next, as shown in FIG. 6B, in the read operation of the first pattern, as opposed to the write operation, the drain current Id flows from the second region 22 toward the first region 21. Whether or not information is written in the integrated side wall structure 46 is determined by the magnitude of the drain current Id. Specifically, at the time of the read operation, the reference voltage (for example, Vds=0 V) is applied to the first region 21 via the first wiring 90, and the positive voltage (for example, Vds =0.5 V) is applied to the second region 22 via the second wiring 91. Then, the gate voltages Vg1 and Vg2 (Vg1=Vg2) applied to the respective first gate electrode 33 and second gate electrode 39 are increased.

In an information memory state (Program), threshold values of the gate voltages Vg1 and Vg2 are higher than those in the initial state (Initial) before writing of information. This is because, if information has been written in the integrated side wall structure 46 (injected with hot electrons HE), it is difficult for electrons to be induced in the vicinity of the first gate electrode 33 and the second gate electrode 39 due to a repulsive force acting between minority carriers (electrons) in the channel region 25 and the hot electrons HE. Therefore, it is possible to determine whether or not information is written by checking whether the gate voltages Vg1 and Vg2 at which the drain current Id starts to flow are higher than the threshold value in the initial state.

Next, referring to FIG. 7, in the initial state prior to the write operation of FIG. 6A, the threshold values of the gate voltages Vg1 and Vg2 are about 1.1 V, whereas the threshold values of the gate voltages Vg1 and Vg2 after the write operation of FIG. 6A is about 4.2 V, which is higher than the threshold values of the gate voltages Vg1 and Vg2 in the initial state. In this way, by comparing the threshold values of the gate voltages Vg1 and Vg2 between the initial state and the memory state, it is possible to determine whether or not information is written.

Next, the second pattern in which the first region 21 of FIG. 4 is the source S and the second region 22 of FIG. 4 is the drain D will be described. As shown in FIG. 8A, the write operation (Program) of the second pattern is achieved by injecting electrons (hot electrons HE), which are generated by impact ionization in the vicinity of the first region 21 (the source S), into the integrated side wall structure 46. Specifically, at a time of the write operation, the reference voltage (for example, Vds=0V) is applied to the first region 21 via the first wiring 90, and the positive voltage (for example, Vds=5V) is applied to the second region 22 via the second wiring 91. At this time, of the first gate electrode 33 and the second gate electrode 39, the first gate electrode 33 on a side closer to the source S is used as the storage gate electrode 94, and the second gate electrode 39 on a side closer to the drain D is used as the selection gate electrode 95. The gate voltage Vg2 higher than the gate voltage (applied voltage) Vg1 of the storage gate electrode 94 is applied to the selection gate electrode 95. For example, the gate voltage of the selection gate electrode 95 may be Vg2=9 V, and the gate voltage of the storage gate electrode 94 may be Vg1=5 V.

As a result, electrons are induced in the vicinity of the first gate electrode 33 and the second gate electrode 39 of the channel region 25 to form a channel, and the drain current Id flows between the source and the drain from the second region 22 toward the first region 21. In the vicinity of the first region 21 (the source S), hot electrons HE are generated by impact ionization caused by electric field concentration. Then, the hot electrons HE are injected into the integrated side wall structure 46 (particularly, the charge storage film 54). As a result, information (data) is written in the integrated side wall structure 46. The gate voltages Vg1 and Vg2 and the drain-source voltage Vds in the write operation are not limited to above values, and can be appropriately changed according to specifications of the semiconductor device 1.

Next, as shown in FIG. 8B, in the read operation of the second pattern, as opposed to the write operation, the drain current Id flows from the first region 21 toward the second region 22. Whether or not information is written in the integrated side wall structure 46 is determined by the magnitude of the drain current Id. Specifically, at the time of the read operation, the reference voltage (for example, Vds=0 V) is applied to the second region 22 via the second wiring 91, and the positive voltage (for example, Vds=0.5 V) is applied to the first region 21 via the first wiring 90. Then, the gate voltages Vg1 and Vg2 applied to the respective first gate electrode 33 and second gate electrode 39 are increased.

In the information memory state (Program), the threshold values of the gate voltages Vg1 and Vg2 are higher than those in the initial state (Initial) before writing of information. This is because, if information has been written in the integrated side wall structure 46 (injected with hot electrons HE), it is difficult for electrons to be induced in the vicinity of the first gate electrode 33 and the second gate electrode 39 due to a repulsive force acting between the minority carriers (electrons) in the channel region 25 and the hot electrons HE. Therefore, it is possible to determine whether or not information is written by checking whether the gate voltages Vg1 and Vg2 at which the drain current Id starts to flow are higher than the threshold value in the initial state.

Next, referring to FIG. 9, in the initial state prior to the write operation of FIG. 8A, the threshold values of the gate voltages Vg1 and Vg2 are about 1.1 V, whereas the threshold values of the gate voltages Vg1 and Vg2 after the write operation of FIG. 8A is about 3.8 V, which is higher than the threshold values of the gate voltages Vg1 and Vg2 in the initial state. In this way, by comparing the threshold values of the gate voltages Vg1 and Vg2 between the initial state and the memory state, it is possible to determine whether or not information is written.

Furthermore, an injection amount of hot electrons HE between the first pattern and the second pattern can be compared by comparing FIGS. 7 and 9. First, the first pattern differs from the second pattern in that the second gate electrode 39 is the storage gate electrode 94 and the first gate electrode 33 is the selection gate electrode 95. In the second pattern, the first gate electrode 33 is the storage gate electrode 94, and the second gate electrode 39 is the selection gate electrode 95. The gate lengths Lg1 and Lg2 of the first gate electrode 33 and the second gate electrode 39 are different from each other. For example, in an evaluation of FIGS. 7 and 9, the first gate length Lg1 = 0.5 µm and the second gate length Lg2 = 0.13 µm.

In comparison between FIGS. 7 and 9, the threshold values of the gate voltages Vg1 and Vg2 in the memory state are higher in the first pattern (FIG. 7) than in the second pattern (FIG. 9). For example, the threshold values of the gate voltages Vg1 and Vg2 of the first pattern are about 4.2 V, while the threshold values of the gate voltages Vg1 and Vg2 of the second pattern are about 3.8 V. The higher the threshold values of the gate voltages Vg1 and Vg2, the more difficult it is for the drain current Id to flow (the more difficult it is for a channel to be formed), so that the amount of hot electrons HE accumulated is large. From this result, it can be seen that, in the single memory transistor structure 45 including the first gate electrode 33 and the second gate electrode 39 having different gate lengths, by setting the second gate electrode 39 having the second gate length Lg2, which is relatively shorter than the first gate length Lg1, as the storage gate electrode 94 and setting the first gate electrode 33 having the first gate length Lg1, which is relatively longer than the second gate length Lg2, as the selection gate electrode 95, the amount of hot electrons HE accumulated is increased, thereby making the write characteristics of a memory excellent.

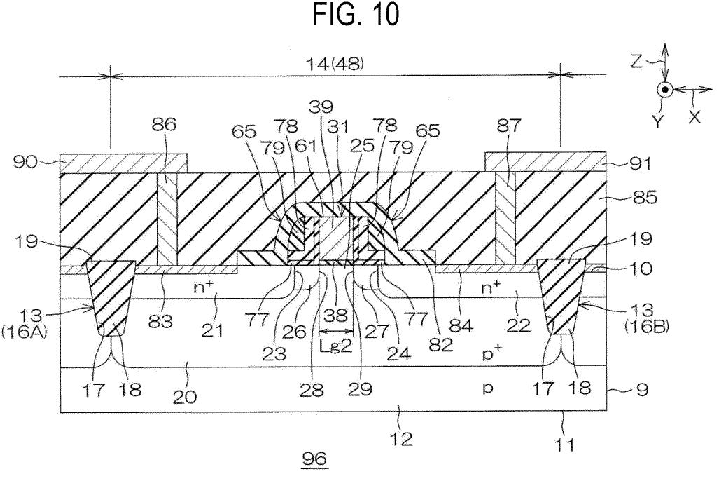

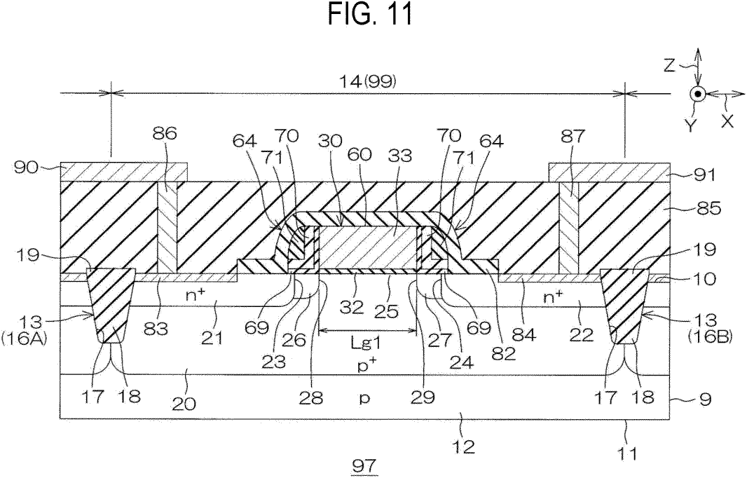

Next, it is evaluated whether or not the write characteristics of the memory can be improved by providing the integrated side wall structure 46. An evaluation is performed based on a comparison between the memory cell 4 including the structure of FIG. 4 and a memory cell 4 (Sample 1) including a structure of FIG. 10/memory cell 4 (Sample 2) including a structure of FIG. 11. First, the structures of Samples 1 and 2 to be compared will be described. FIGS. 10 and 11 are schematic cross-sectional views of semiconductor devices 96 and 97 according to Sample 1 and Sample 2, respectively.

Referring to FIG. 10, the semiconductor device 96 is different from the semiconductor device 1 of FIG. 4 in that the former does not include the first planar gate structure 30. Therefore, the memory cell 4 of the semiconductor device 96 of FIG. 10 is provided with a memory transistor structure 98 including only the second planar gate structure 31. Referring to FIG. 11, the semiconductor device 97 is different from the semiconductor device 1 of FIG. 4 in that the former does not include the second planar gate structure 31. Therefore, the memory cell 4 of the semiconductor device 97 of FIG. 11 is provided with a memory transistor structure 99 including only the first planar gate structure 30.

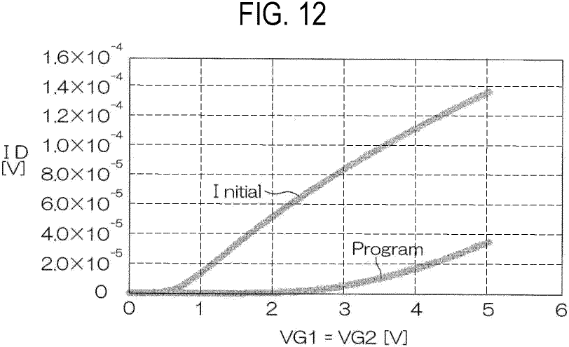

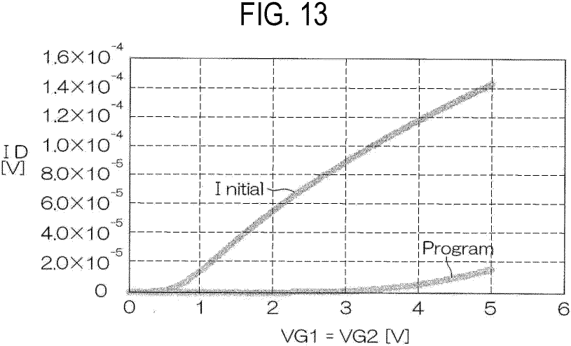

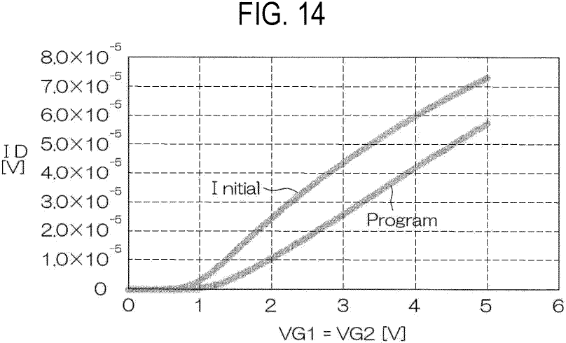

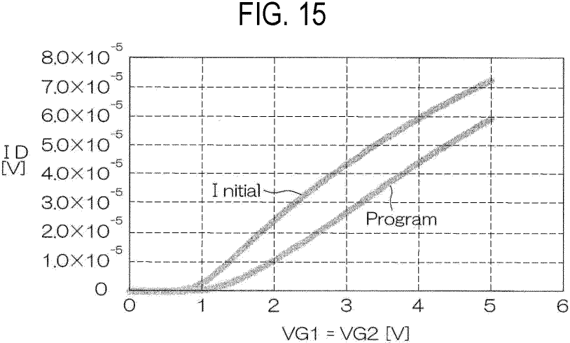

FIGS. 12 and 13 are diagrams for comparing magnitudes of drain currents in an initial state and a memory state of Sample 1, respectively. FIGS. 14 and 15 are diagrams for comparing magnitudes of drain currents in an initial state and a memory state of Sample 2, respectively. FIGS. 12 and 14 show results obtained when the gate voltage Vg=5 V is applied to the storage gate electrode 94 at a time of writing, as in the case of FIGS. 7 and 9. FIGS. 13 and 15 show results obtained when the gate voltage Vg=9V is applied to the storage gate electrode 94 at a time of writing. In FIGS. 12 to 15, the horizontal axis represents the magnitude of the gate voltage Vg1 or the gate voltage Vg2, and the vertical axis represents the magnitude of the drain current Id.

First, FIGS. 7 and 9 are compared with FIGS. 12 and 14. These figures show the results obtained when all of the gate voltages at the time of writing are 5 V. Referring to FIGS. 7 and 9, in the memory cell 4 provided with the integrated side wall structure 46, the threshold values of the gate voltages Vg1 and Vg2 after the write operation are about 4.2 V and about 3.8 V, respectively. In contrast, referring to FIGS. 12 and 14, in the memory cell 4 not provided with the integrated side wall structure 46, the gate threshold voltages are about 2.7 V (Sample 1, the second gate length Lg2=0.13 µm) and about 1.3 V (Sample 2, the first gate length Lg1=0.5 µm), respectively. In this way, since the threshold value of the gate voltage after writing is high when the integrated side wall structure 46 is provided, it can be seen that the integrated side wall structure 46 contributes to the increase in the amount of hot electrons HE accumulated.

On the other hand, in the result of Sample 1 in FIG. 13, the threshold value of the gate voltage after writing is a relatively high value of about 3.7 V, and it is considered that a relatively large amount of hot electrons HE is accumulated. However, FIG. 13 is the result obtained when the write gate voltage is 9 V. That is, in order to achieve the same accumulation amount of hot electrons as in FIGS. 7 and 9, a higher write gate voltage is required than that in a case of including the integrated side wall structure 46. Further, from the result of FIG. 15, in Sample 2, even if the write gate voltage is set to 9 V, the threshold value of the gate voltage after writing is as low as about 1.5 V.

From the above, it can be seen that, in the memory cell 4 provided with the integrated side wall structure 46, the accumulation amount of hot electrons can be improved even if the gate voltage at the time of writing is not high. As a result, it is possible to provide the semiconductor device 1 having excellent write characteristics of the memory. It is considered that this is because the electric charges can be accumulated not only in the vicinity of the first side portion 34 of the first gate electrode 33 but also in the space region 40 by forming the integrated side wall structure 46. That is, a length of the side wall structure extending in the first direction from the first side portion 34 of the first gate electrode 33 can be increased. As a result, the amount of electric charges accumulated in the side wall structure can be increased over Sample 1 and Sample 2 in which the side wall structures are independently formed on the first gate electrode 33 and the second gate electrode 39, respectively. Therefore, the write characteristics of the memory can be improved.

### Method of Manufacturing Semiconductor Device 1

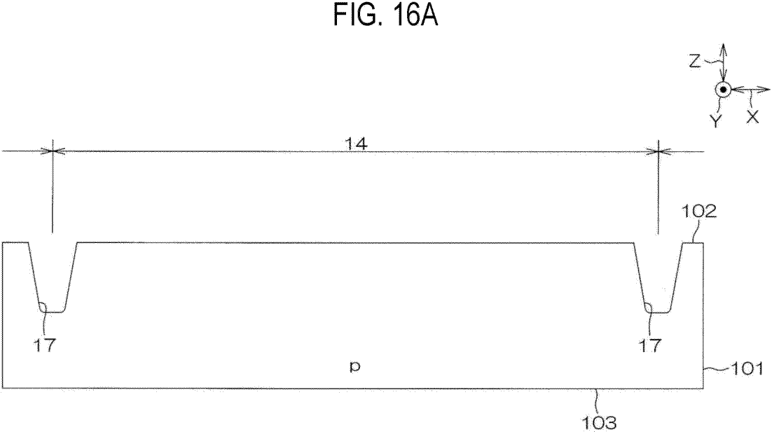

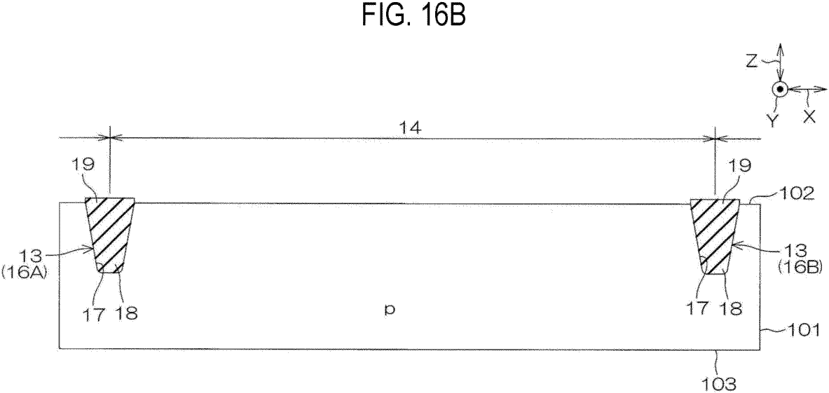

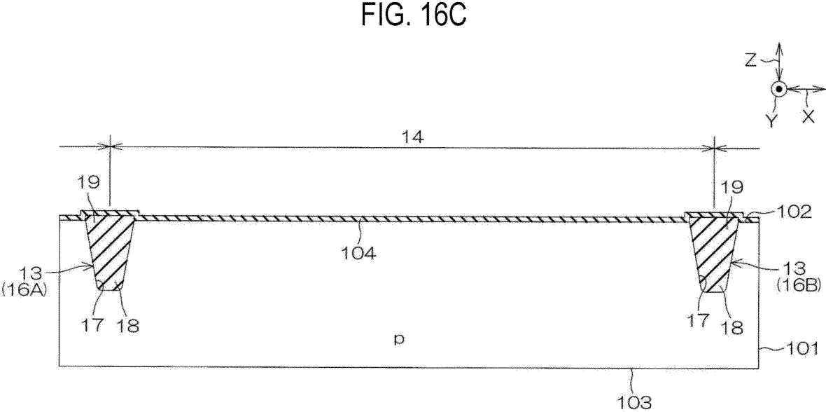

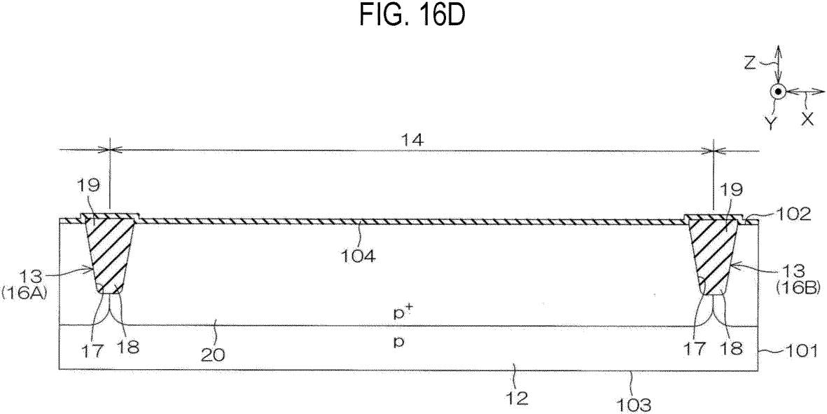

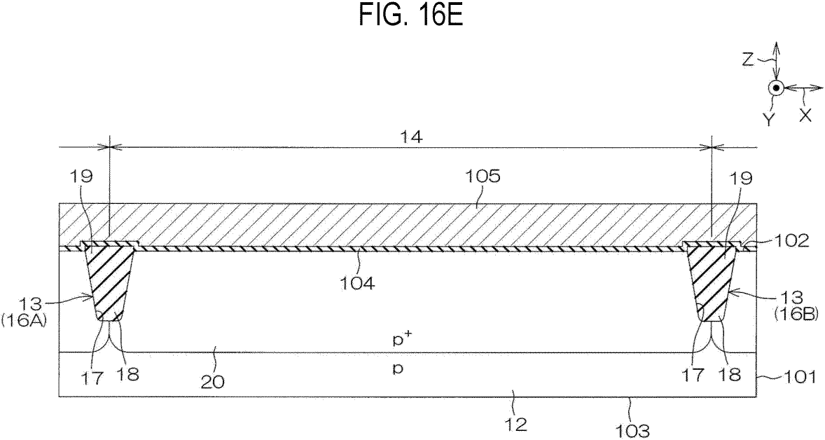

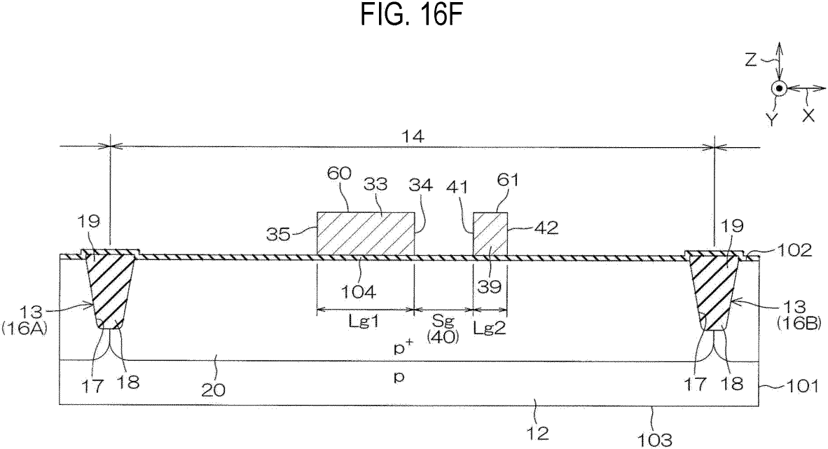

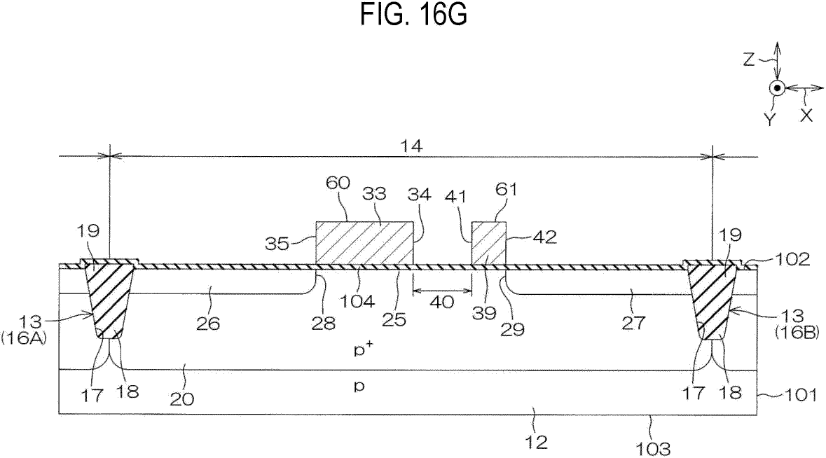

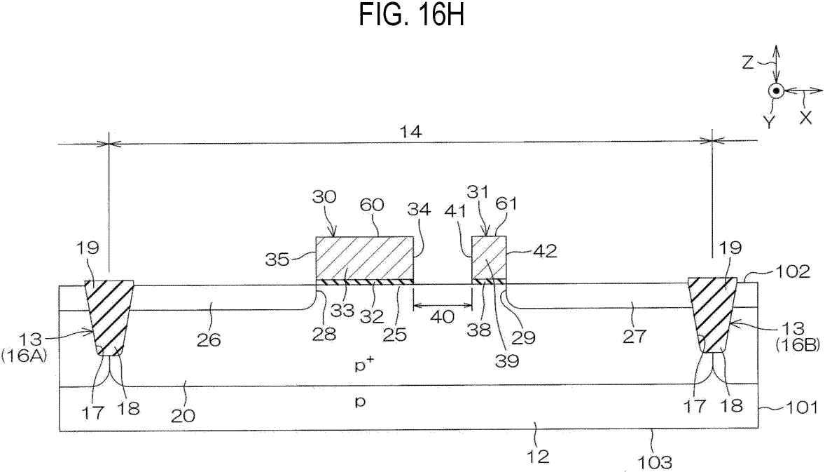

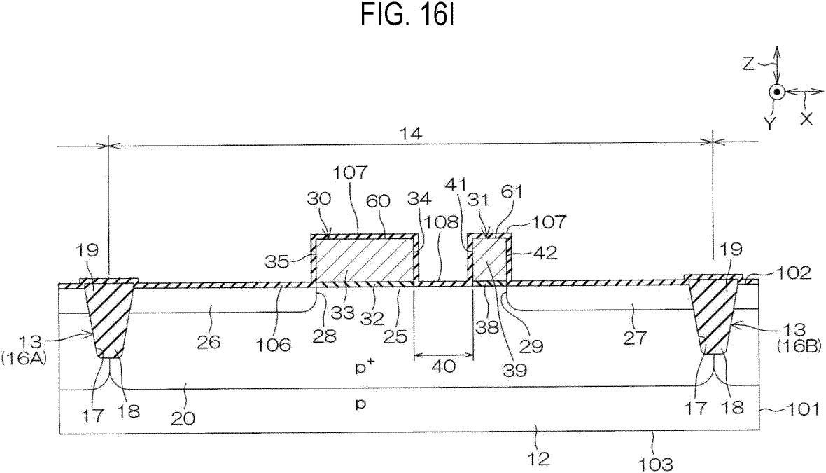

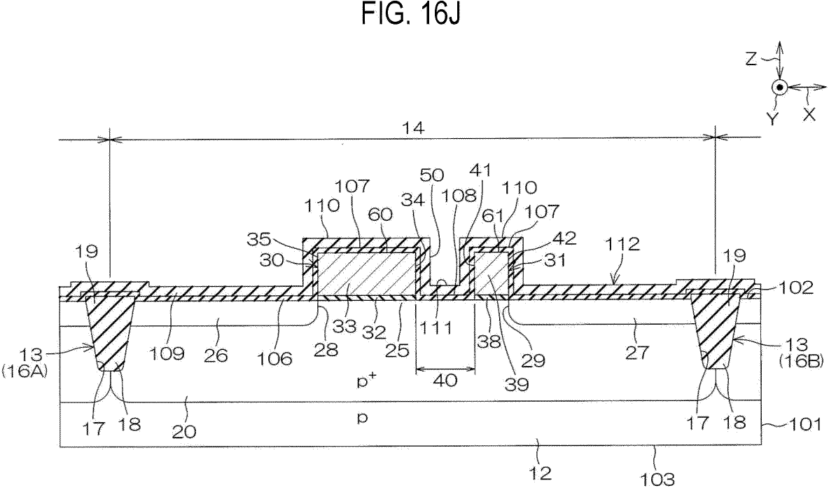

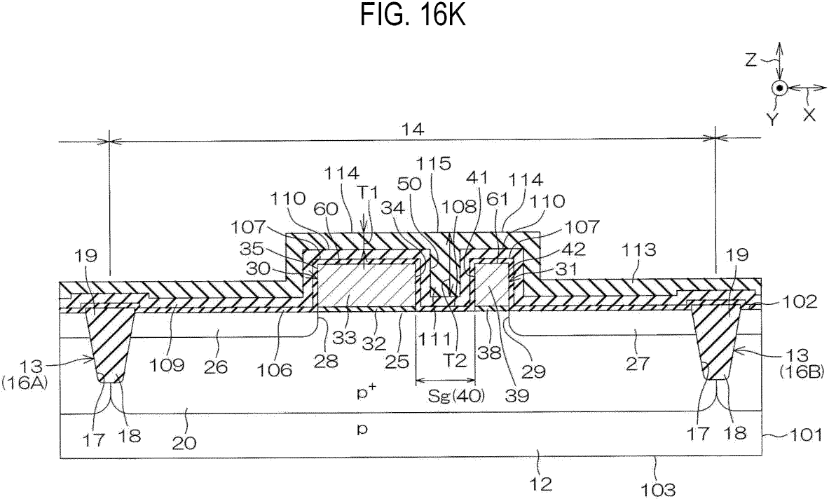

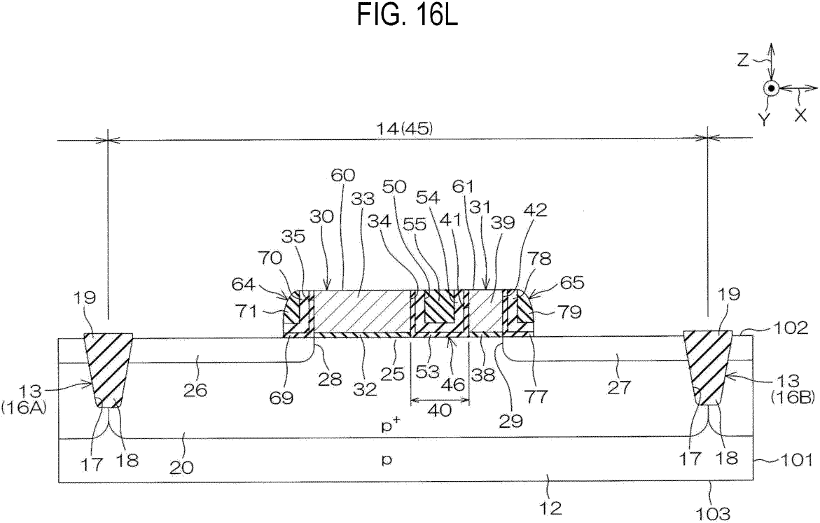

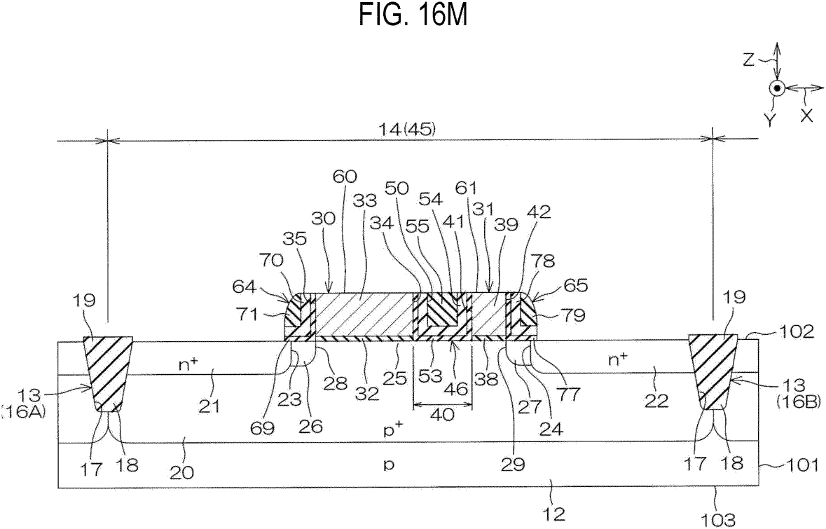

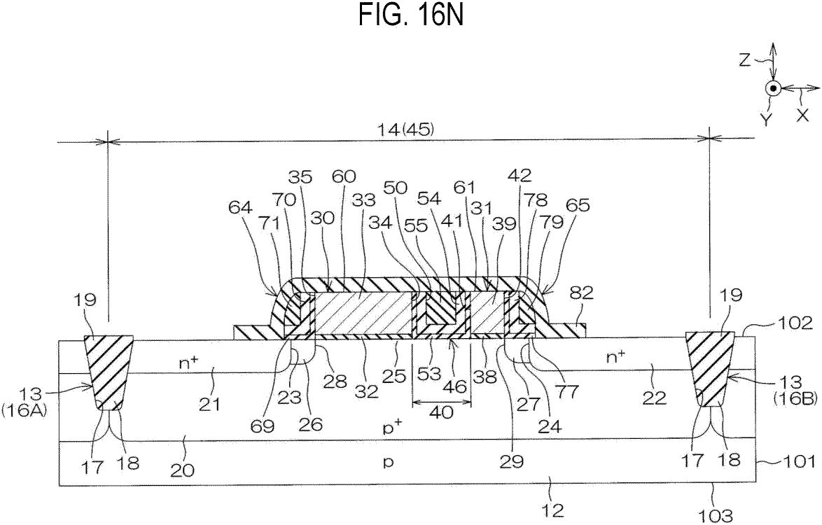

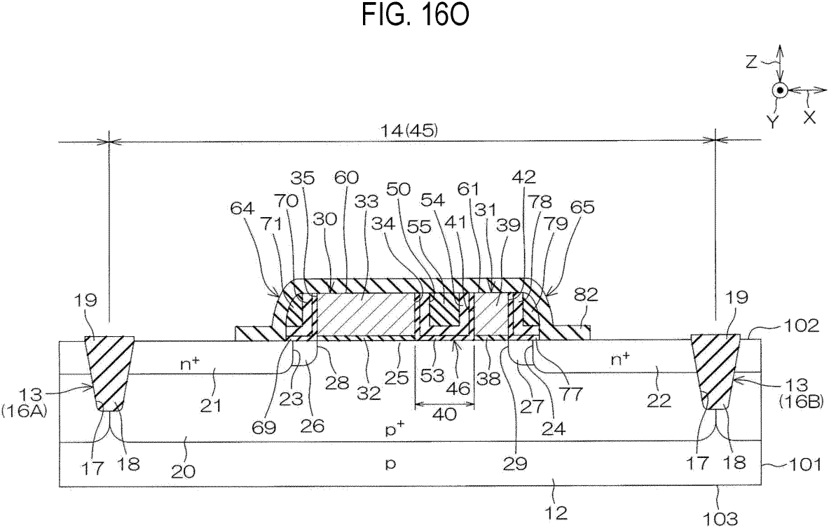

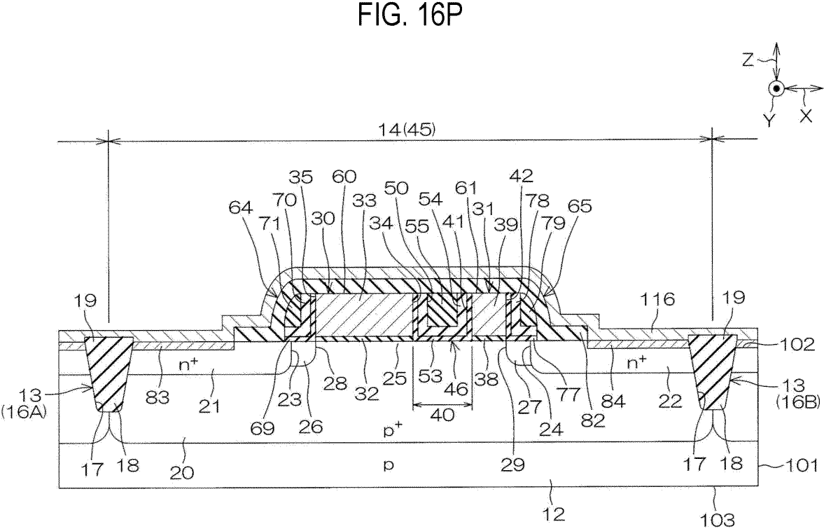

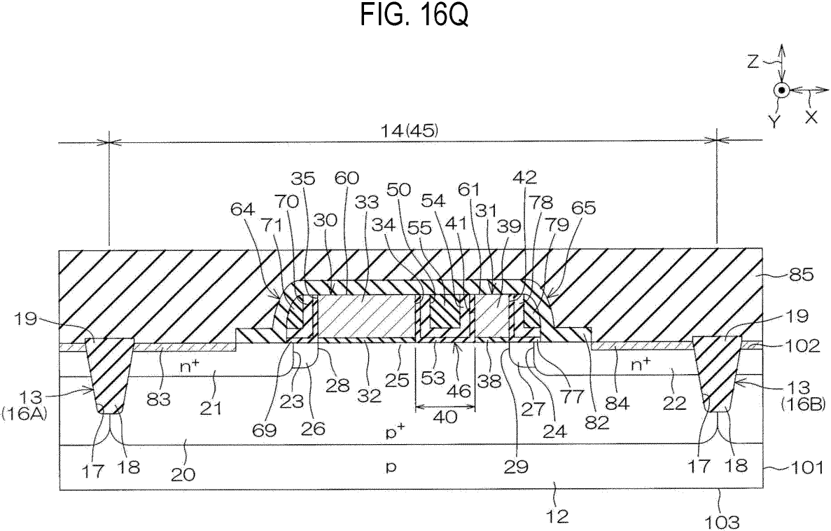

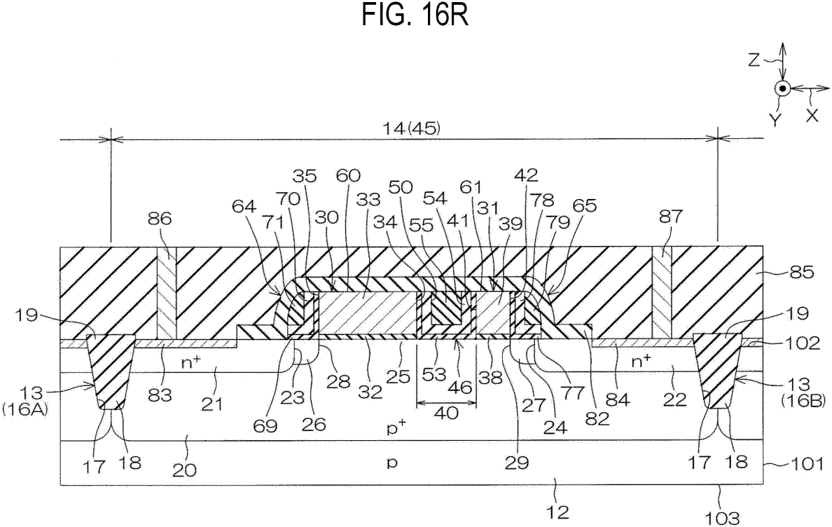

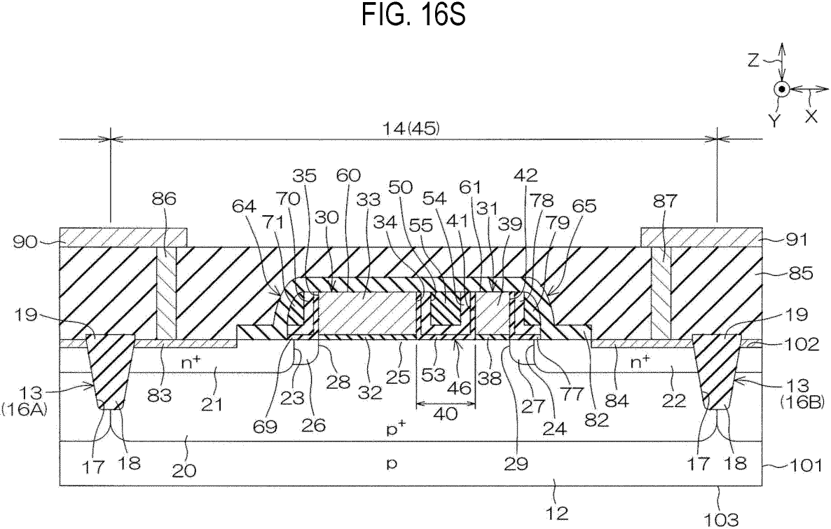

FIGS. 16A to 16S are views showing a portion of a process of manufacturing the semiconductor device 1 in the process order. FIGS. 16A to 16S correspond to the same cross section as that in FIG. 4.

First, referring to FIG. 16A, a semiconductor wafer 101 is prepared. The semiconductor wafer 101 serves as a base for the semiconductor layer 9. The semiconductor wafer 101 includes a first wafer main surface 102 on one side and a second wafer main surface 103 on the opposite side. The first wafer main surface 102 and the second wafer main surface 103 correspond to the first main surface 10 and the second main surface 11 of the semiconductor layer 9, respectively (see FIG. 4). Next, a portion of the semiconductor wafer 101 is selectively removed from the first wafer main surface 102 by etching through a mask (not shown) having a predetermined pattern. As a result, the trench 17 for partitioning the memory cell region 14 is formed. The etching may be, for example, dry etching (for example, an RIE method) or wet etching. In this embodiment, the trench 17 is formed by dry etching.

Next, referring to FIG. 16B, a base insulating film (not shown), which is a base of the insulator 18, is formed on the first wafer main surface 102 to backfill the trench 17. In this embodiment, the base insulating film is made of silicon oxide. The base insulating film may be formed by a CVD method. Next, an unnecessary portion of the base insulating film is removed by etching. As a result, the insulator 18 buried in the trench 17 is formed.

Next, referring to FIG. 16C, a gate insulating film 104, which is a base for the first gate insulating film 32 (see FIG. 4) and the second gate insulating film 38 (see FIG. 4), is formed on the first wafer main surface 102. The gate insulating film 104 is formed, for example, by thermally oxidizing a surface layer portion of the first wafer main surface 102 in a form of a film. Next, referring to FIG. 16D, the p-type well region 20 is formed on the surface layer portion of the first wafer main surface 102 in the memory cell region 14. Specifically, the well region 20 is formed by introducing p-type impurities into the surface layer portion of the first wafer main surface 102 by an ion implantation method via the gate insulating film 104. By forming the well region 20, a region of the semiconductor wafer 101 having a lower p-type impurity concentration than the well region 20 becomes the back gate region 12. The p-type impurities may be introduced into the first wafer main surface 102 at any timing. For example, the p-type impurity may be introduced into the first wafer main surface 102 before a formation of the gate insulating film 104. In that case, a sacrificial oxide film may be formed on the first wafer main surface 102, and p-type impurities may be introduced into the first wafer main surface 102 via the sacrificial oxide film. Then, after the sacrificial oxide film is removed, the gate insulating film 104 is formed.

Next, referring to FIG. 16E, a base electrode 105, which is a base of the first gate electrode 33 and the second gate electrode 39 (see FIG. 4), is formed over the first wafer main surface 102 to cover the gate insulating film 104 and the insulator 18. In this embodiment, the base electrode 105 is made of conductive polysilicon. The base electrode 105 may be formed by, for example, a CVD method.

Next, referring to FIG. 16F, an unnecessary portion of the base electrode 105 is removed by etching via a mask (not shown) having a predetermined pattern. As a result, the first gate electrode 33 and the second gate electrode 39 are formed at the same time. The etching may be, for example, dry etching (for example, an RIE method) or wet etching. The first gate electrode 33 and the second gate electrode 39 are formed with the space region 40 having the predetermined width Sg empty. The first length Lg1 (first gate length) of the first gate electrode 33 in the first direction X may be, for example, 0.4 µm or more and 1 µm or less. The second length Lg2 (second gate length) of the second gate electrode 39 in the first direction X may be, for example, 0.1 µm or more and 0.4 µm or less. The width Sg of the space region 40 may be, for example, 0.1 µm or more and 0.2 µm or less.

Next, referring to FIG. 16G, the n-type first low-concentration impurity region 26 and the n-type second low-concentration impurity region 27 are formed at the surface layer portion of the well region 20. In this embodiment, the first low-concentration impurity region 26 and the second low-concentration impurity region 27 are formed by introducing n-type impurities into the surface layer portion of the well region 20 by an ion implantation method using the first gate electrode 33 and the second gate electrode 39 as a mask. That is, the first low-concentration impurity region 26 is formed in a self-aligned manner with respect to the first gate electrode 33, and the second low-concentration impurity region 27 is formed in a self-aligned manner with respect to the second gate electrode 39.

Next, referring to FIG. 16H, the gate insulating film 104 is partially removed by etching. As a result, the gate insulating film 104 is separated into the first gate insulating film 32 and the second gate insulating film 38 to form the first planar gate structure 30 and the second planar gate structure 31. Next, referring to FIG. 16I, a lower base insulating film 106, which is a base for the memory insulating film 53, the first lower layer film 69, and the second lower layer film 77, is formed. The lower base insulating film 106 integrally covers the first wafer main surface 102, the first gate electrode 33, the space region 40, and the second gate electrode 39. The lower base insulating film 106 has a constant thickness. In FIG. 16I, the lower base insulating film 106 includes a first portion 107 on each of the upper surfaces 60 and 61 of the first gate electrode 33 and the second gate electrode 39, and a second portion 108 having the same thickness as the first portion 107 in the space region 40. The lower base insulating film 106 may be formed by thermally oxidizing the first wafer main surface 102, the first gate electrode 33, the space region 40, and the second gate electrode 39 in a form of a film. Of course, the lower base insulating film 106 may be formed by a CVD method.

Next, referring to FIG. 16J, an upper base insulating film 109, which is a base of the charge storage film 54, the first upper layer film 70, and the second upper layer film 78, is formed on the lower base insulating film 106. The upper base insulating film 109 integrally covers the first wafer main surface 102, the first gate electrode 33, the space region 40, and the second gate electrode 39. The upper base insulating film 109 has a constant thickness. In FIG. 16J, the upper base insulating film 109 includes a first portion 110 on each of the upper surfaces 60 and 61 of the first gate electrode 33 and the second gate electrode 39, and a second portion 111 having the same thickness as the first portion 110 in the space region 40. The upper base insulating film 109 may be formed by, for example, a CVD method. The lower base insulating film 106 and the upper base insulating film 109 that form a storage structure of the memory may be collectively referred to as a first base insulating film 112. In the space region 40, the recess 50 sandwiched between the first gate electrode 33 and the second gate electrode 39 is formed on the first base insulating film 112.

Next, referring to FIG. 16K, a second base insulating film 113, which is a base of the insulating spacer 55, the first insulating spacer 71, and the second insulating spacer 79, is formed on the first base insulating film 112. The second base insulating film 113 may be formed by, for example, a CVD method. The second base insulating film 113 integrally covers the first wafer main surface 102, the first gate electrode 33, the space region 40, and the second gate electrode 39. In FIG. 16K, the second base insulating film 113 includes a first portion 114 on each of the upper surfaces 60 and 61 of the first gate electrode 33 and the second gate electrode 39, and a second portion 115 in the space region 40. The first portion 114 has a first thickness T1 and the second portion 115 has a second thickness T2 larger than the first thickness T1.

The reason that the first portion 114 and the second portion 115 having different thicknesses are formed in the second base insulating film 113 is the width Sg of the space region 40. When the width Sg of the space region 40 is within a predetermined range (in this embodiment, 0.1 µm or more and 0.2 µm or less), deposition of an insulating material of the second base insulating film 113 proceeds in the recess 50 on the space region 40 from both the first side portion 34 of the first gate electrode 33 and the third side portion 41 of the second gate electrode 39. For example, when the first thickness T1 is secured in the first portion 114, the insulating material is deposited in the recess 50 in a lateral direction by twice the first thickness T1. Therefore, the second portion 115, which is thicker than the first portion 114, is formed in the recess 50.

Next, referring to FIG. 16L, the first portion 114 of the second base insulating film 113, the first portions 107 and 110 of the first base insulating film 112, and a portion covering the first wafer main surface 102 of these insulating films are selectively removed by etch-back. As a result, the upper surfaces 60 and 61 of the first gate electrode 33 and the second gate electrode 39 are exposed. Further, the first side wall structure 64, the second side wall structure 65, and the integrated side wall structure 46 are formed by the first base insulating film 112 and the second base insulating film 113 remaining in the first gate electrode 33, the second gate electrode 39, and the space region 40. The second base insulating film 113 remaining in the recess 50 forms the insulating spacer 55. At this time, depending on a degree of progress of etch-back, the upper surface 62 of the insulating spacer 55 may be formed flat (see FIG. 5A), or the recess 63 may be formed on the upper surface 62 of the insulating spacer 55 (FIG. 5B). Next, referring to FIG. 16M, the n-type first region 21 and the n-type second region 22 are formed at the surface layer portion of the well region 20. In this embodiment, the first region 21 and the second region 22 are formed by introducing n-type impurities into the surface layer portion of the well region 20 by an ion implantation method using the first side wall structure 64, the first planar gate structure 30, the integrated side wall structure 46, the second planar gate structure 31, and the second side wall structure 65 as a mask. That is, the first region 21 is formed in a self-aligned manner with respect to the first side wall structure 64, and the second region 22 is formed in a self-aligned manner with respect to the second side wall structure 65.

Next, referring to FIG. 16N, the coating insulating film 82 is formed to cover the memory cell region 14 and the insulator 18. The coating insulating film 82 may be formed by, for example, a CVD method. Next, referring to FIG. 16O, an unnecessary portion of the coating insulating film 82 is removed by etching via a mask (not shown) having a predetermined pattern. As a result, portions of the first region 21 and the second region 22 are exposed.

Next, referring to FIG. 16P, the first silicide film 83 and the second silicide film 84 are formed. In this step, first, a metal film 116 that covers the entire memory cell region 14 is formed. The metal film 116 contains at least one of Ti, Ni, Co, Mo, and W. The metal film 116 may be formed, for example, by a sputtering method or a vapor deposition method. Next, a portion of the first wafer main surface 102 in contact with the metal film 116 is silicided. The silicidization may be carried out by an annealing method (for example, an RTA (rapid thermal anneal) method). As a result, the first silicide film 83 and the second silicide film 84 containing at least one of TiSi, TiSi₂, NiSi, CoSi, CoSi₂, MoSi₂, and WSi₂ are formed. The metal film 116 is then removed.

Next, referring to FIG. 16Q, the interlayer insulating film 85 is formed over the first wafer main surface 102. The interlayer insulating film 85 may be formed by, for example, a CVD method. Next, referring to FIG. 16R, after a contact hole is formed by etching via a mask (not shown) having a predetermined pattern, the first contact 86, the second contact 87, the first gate contact 88 (see FIG. 3), and the second gate contact 89 (see FIG. 3) are formed in the contact hole.

Next, referring to FIG. 16S, a base wiring film, which is a base for the plurality of wirings, is formed and patterned on the interlayer insulating film 85, thereby forming the first wiring 90, the second wiring 91, the first gate wiring 92 (see FIG. 3), and the second gate wiring 93 (see FIG. 3). After that, the semiconductor wafer 101 is cut, and a plurality of semiconductor devices 1 are cut out. The semiconductor device 1 is manufactured through the process including the above steps.

According to the above method, in a step of FIG. 16K, the second portion 115 of the second base insulating film 113 has the second thickness T2 that is relatively thicker than the first thickness T1in the space region 40 between the first gate electrode 33 and the second gate electrode 39. As a result, during the etch-back in a step of FIG. 16L, the second portions 108 and 111 of the first base insulating film 112 on the space region 40 are protected by the second portion 115 of the second base insulating film 113. As a result, since the first base insulating film 112 is not divided in the space region 40, the integrated side wall structure 46 can be formed.

According to the obtained semiconductor device 1, the integrated side wall structure 46 is formed on the first side portion 34 of the first gate electrode 33. As a result, electric charges can be accumulated in the integrated side wall structure 46 not only in the vicinity of the first side portion 34 of the first gate electrode 33 but also in the space region 40. That is, the length of the side wall structure extending from the first side portion 34 of the first gate electrode 33 in the first direction X can be increased. As a result, the accumulation amount of electric charges in the side wall structure can be increased over a case where the side wall structures are independently formed on the first gate electrode 33 and the second gate electrode 39, respectively. Therefore, the write characteristics of the memory can be improved.

Although the embodiments of the present disclosure have been described, the present disclosure can also be implemented in other embodiments. For example, in the above-described embodiments, an example in which the first conduction type is n-type and the second conduction type is p-type has been described, but the first conduction type may be p-type and the second conduction type may be n-type. A specific configuration in this case is obtained by replacing the n-type region with a p-type region and replacing the p-type region with an n-type region in the above description and the accompanying drawings.

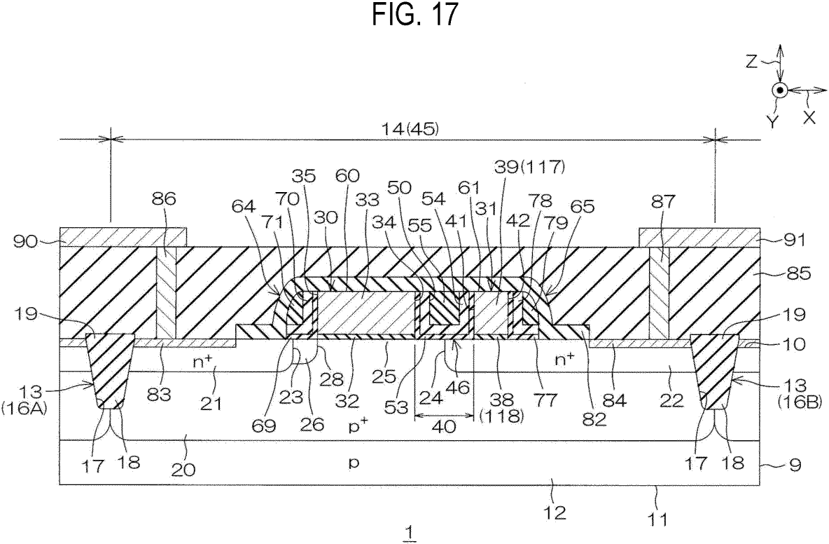

Further, in the above-described embodiments, the integrated side wall structure 46 is exemplified as a common side wall structure for the first planar gate structure 30 and the second planar gate structure 31, but the side wall structure 46 may not be of an integrated type. Further, in the above-described embodiments, the first gate electrode 33 and the second gate electrode 39 are arranged across the space region 40 having the predetermined width Sg in order to form the integrated side wall structure 46. However, for example, one of the first gate electrode 33 and the second gate electrode 39 may not function as a gate electrode. For example, as shown in FIG. 17, in the third direction Z, the second region 22 may overlap the first planar gate structure 30 side with respect to the second planar gate structure 31 and may face the integrated side wall structure 46. The second planar gate structure 31 becomes a depletion type MISFET in which both sides thereof in the first direction X are conducted by the second region 22 (a state in which a channel is formed), and does not function as a gate electrode for channel formation. In this case, the second gate electrode 39 and the second gate insulating film 38 may be referred to as a first conductive layer 117 and a first insulating film 118, respectively.

From the above, the embodiments of the present disclosure are exemplary in all respects and should not be construed in a limited manner, and are intended to include changes in all respects. The features described below may be extracted from the description in the present disclosure and the drawings.

### Supplementary Note 1-1

A semiconductor device (1) including:
a semiconductor layer (9) including a first main surface (10);
a first region (21) of a first conduction type that is formed at a surface layer portion of the first main surface (10);
a second region (22) of a first conduction type that is formed at the surface layer portion of the first main surface (10) and is separated from the first region (21) in a first direction (X);
a channel region (25) of a second conduction type that is formed between the first region (21) and the second region (22) in the surface layer portion of the first main surface (10);
a first gate electrode (33) that is formed in a vicinity of the first region (21) in the first main surface (10), faces the channel region (25), and includes a first side portion (34) and a second side portion (35) on an opposite side of the first side portion in the first direction (X);
a first gate insulating film (32) formed between the first gate electrode (33) and the semiconductor layer (9);
a first conductive layer (39,117) that is formed in a vicinity of the second region (22) in the first main surface (10), is separated from the first gate electrode (33) across a space region (40) having a predetermined width in the first direction (X), and includes a third side portion (41) facing the first side portion (34) of the first gate electrode (33) and a fourth side portion (42) on an opposite side of the third side portion;
a first insulating film (38, 118) formed between the first conductive layer (39,117) and the semiconductor layer (9); and
a side wall structure (46) that covers the first side portion (34) of the first gate electrode (33), the third side portion (41) of the first conductive layer (39,117), and the first main surface (10) in the space region (40), and is formed in common to the first gate electrode (33) and the first conductive layer (39,117).

According to this configuration, a side wall structure (46) is formed at the first side portion (34) of the first gate electrode (33). As a result, electric charges can be accumulated in the side wall structure (46) not only in the vicinity of the first side portion (34) of the first gate electrode (33) but also in the space region (40). That is, a length of the side wall structure extending from the first side portion (34) of the first gate electrode (33) in the first direction (X) can be increased. As a result, an accumulation amount of electric charges in the side wall structure can be increased over a case where side wall structures are independently formed on the first gate electrode (33) and the first conductive layer (39,117), respectively. Therefore, write characteristics of a memory can be improved.

### Supplementary Note 1-2

The semiconductor device (1) of Supplementary Note 1-1, further comprising: an element isolation portion (13) that partitions a plurality of memory cell regions (14) is included in the semiconductor layer (9),
wherein the first gate electrode (33) and the first conductive layer (39) are formed between the first region (21) and the second region (22) in each of the memory cell regions (14) and form a single memory transistor structure (45) in cooperation with the first region (21) and the second region (22),
wherein the first gate electrode (33) includes a storage gate electrode (94) in which a voltage for accumulating electric charges is applied to the side wall structure (46), and
wherein the first conductive layer (39) includes a selection gate electrode (95) to which a voltage for selecting each of the memory cell regions (14) as a charge storage target cell is applied.

### Supplementary Note 1-3

The semiconductor device (1) of Supplementary Note 1-1 or 1-2, wherein the side wall structure (46) includes a base portion (47) formed on the first main surface (10), a first wall portion (48) erected along the first side portion (34) of the first gate electrode (33) from the base portion (47), and a second wall portion (49) erected along the third side portion (41) of the first conductive layer (39,117) from the base portion (47).

### Supplementary Note 1-4

The semiconductor device (1) of Supplementary Note 1-3, wherein the side wall structure (46) further includes an insulating spacer (55) formed in a space sandwiched between the first wall portion (48) and the second wall portion (49) in the first direction (X).

### Supplementary Note 1-5

The semiconductor device (1) of Supplementary Note 1-4, wherein the insulating spacer (55) includes a silicon oxide film.

### Supplementary Note 1-6

The semiconductor device (1) of any one of Supplementary Notes 1-1 to 1-5, wherein, in the first direction (X), the first gate electrode (33) has a first length (Lg1), and the first conductive layer (39,117) has a second length (Lg2) different from the first length (Lg1).

According to this configuration, the first gate electrode (33) and the first conductive layer (39,117) having different gate lengths are arranged adjacent to each other. As a result, it is possible to select whether to use the first gate electrode (33) or the first conductive layer (39,117) as the memory transistor according to characteristics required for the semiconductor device (1).

### Supplementary Note 1-7

The semiconductor device (1) of Supplementary Note 1-6, wherein the first length (Lg1) is larger than the second length (Lg2).

### Supplementary Note 1-8

The semiconductor device (1) of Supplementary Note 1-7, wherein the first length (Lg1) is 0.4 µm or more and 1 µm or less, and the second length (Lg2) is 0.1 µm or more and 0.4 µm or less.

### Supplementary Note 1-9

The semiconductor device (1) of any one of Supplementary Notes 1-1 to 1-8, wherein, in the first direction (X), a third length (Sg) of the space region (40) is 0.1 µm or more and 0.2 µm or less.

### Supplementary Note 1-10

The semiconductor device (1) of any one of Supplementary Notes 1-1 to 1-9, wherein the side wall structure (46) includes a lower layer film (53) in contact with the first side portion (34), the third side portion (41), and the first main surface (10), and an upper layer film (54) that is laminated on the lower layer film (53) and contains an insulating material different from an insulating material of the lower layer film (53).

### Supplementary Note 1-11

The semiconductor device (1) of Supplementary Note 1-10, wherein the lower layer film (53) includes a silicon oxide film, and
wherein the upper layer film (54) includes a silicon nitride film.

### Supplementary Note 1-12

The semiconductor device (1) of Supplementary Note 1-10 or 1-11, wherein the upper layer film (54) has a thickness larger than a thickness of the lower layer film (53).

### Supplementary Note 1-13

The semiconductor device (1) of any one of Supplementary Notes 1-1 to 1-12, further including: a first low-concentration impurity region (26) that is formed in a self-aligned manner with respect to the second side portion (35) of the first gate electrode (33) between the first region (21) and the channel region (25) and has an impurity concentration lower than an impurity concentration of the first region (21).

### Supplementary Note 1-14

The semiconductor device (1) of any one of Supplementary Notes 1-1 to 1-13, further including: a second low-concentration impurity region (27) that is formed in a self-aligned manner with respect to the fourth side portion (42) of the first conductive layer (39,117) between the second region (22) and the channel region (25) and has an impurity concentration lower than an impurity concentration of the second region (22).

### Supplementary Note 1-15

The semiconductor device (1) of any one of Supplementary Notes 1-1 to 1-14, further including: a coating insulating film (82) that integrally covers a portion of the first region (21), the first gate electrode (33), the first conductive layer (39,117), and a portion of the second region (22).

### Supplementary Note 1-16

The semiconductor device (1) of Supplementary Note 1-15, wherein the semiconductor layer (9) includes a Si semiconductor layer (9), and
wherein the semiconductor device further comprises a silicide film (83, 84) formed in a portion exposed from the coating insulating film (82) is included in the first region (21) and the second region (22).

### Supplementary Note 1-17

The semiconductor device (1) of any one of Supplementary Notes 1-1 to 1-16, wherein the first gate electrode (33) and the first conductive layer (39,117) include a polysilicon layer.

### Supplementary Note 1-18

The semiconductor device (1) of any one of Supplementary Notes 1-1 to 1-17, wherein the side wall structure (46) includes an integrated side wall structure (46) that integrally covers the first side portion (34) of the first gate electrode (33), the third side portion (41) of the first conductive layer (39,117), and the first main surface (10) in the space region (40).

### Supplementary Note 1-19

A method of manufacturing a semiconductor device (1), including:
a first step of forming a first gate electrode (33) and a first conductive layer (39,117) on a first main surface (102) of a semiconductor layer (101) including the first main surface (102), wherein the first gate electrode (33) and the first conductive layer (39,117) separate a space region (40) having a predetermined width in a first direction (X), the first gate electrode (33) includes a first side portion (34) and a second side portion (35) on an opposite side of the first side portion in the first direction (X), and the first conductive layer (39,117) includes a third side portion (41) facing the first side portion (34) of the first gate electrode (33) and a fourth side portion (42) on an opposite side of the third side portion;
a second step of forming a first base insulating film (112) at the first main surface (102) to integrally cover the first gate electrode (33), the space region (40), and the first conductive layer (39,117), wherein the first base insulating film (112) includes a first portion (107, 110) on upper surfaces (60, 61) of the first gate electrode (33) and the first conductive layer (39, 117) and includes a second portion (108, 111) in the space region (40);
a third step of forming a second base insulating film (113) on the first base insulating film (112) to integrally cover the first gate electrode (33), the space region (40), and the first conductive layer (39,117), wherein the second base insulating film (113) includes a first portion (114) having a first thickness (T1) on the first portion (107, 110) of the first base insulating film (112), and the space region (40) includes a second portion (115) having a second thickness (T2) larger than the first thickness (T1);
a fourth step of selectively removing the first portion (114) of the second base insulating film (113) and the first portion (107, 110) of the first base insulating film (112) by etch-back to expose the upper surfaces (60, 61) of the first gate electrode (33) and the first conductive layer (39, 117), wherein the first side portion (34) of the first gate electrode (33), the third side portion (41) of the first conductive layer (39, 117), and the first main surface (102) in the space region (40) are integrally covered by the second portion (108, 111) of the first base insulating film (112) and the second portion (115) of the second base insulating film (113) to form an integrated side wall structure (46) common to the first gate electrode (33) and the first conductive layer (39,117);
a fifth step of forming a first region (21) of a first conduction type in a vicinity of the second side portion (35) of the first gate electrode (33) in a surface layer portion of the first main surface (102); and
a sixth step of forming a second region (22) of a first conduction type in a vicinity of the fourth side portion (42) of the first conductive layer (39,117) in the surface layer portion of the first main surface (102).

According to this configuration, the second portion (115) of the second base insulating film (113) has the second thickness (T2) that is relatively thicker than the first thickness (T1) in the space region (40) between the first gate electrode (33) and the first conductive layer (39,117). As a result, during the etch-back in the fourth step, the second portion (108,111) of the first base insulating film (112) on the space region (40) is protected by the second portion (115) of the second base insulating film (113). As a result, since the first base insulating film (112) is not divided in the space region (40), the integrated side wall structure (46) can be formed.

According to the obtained semiconductor device (1), the integrated side wall structure (46) is formed at the first side portion (34) of the first gate electrode (33). As a result, electric charges can be accumulated in the integrated side wall structure (46) not only in the vicinity of the first side portion (34) of the first gate electrode (33) but also in the space region (40). That is, the length of the side wall structure extending from the first side portion (34) of the first gate electrode (33) in the first direction (X) can be increased. As a result, the accumulation amount of electric charges in the side wall structure is increased over a case where the side wall structures are independently formed on the first gate electrode (33) and the first conductive layer (39,117), respectively. Therefore, the write characteristics of the memory can be improved.

### Supplementary Note 1-20

The method of Supplementary Note 1-19, wherein the first step includes a step of forming the first gate electrode (33) having a first length (Lg1) in the first direction (X) and the first conductive layer (39,117) having a second length (Lg2) different from the first length (Lg1).

### Supplementary Note 1-21

The method of Supplementary Note 1-19 or 1-20, wherein the first step includes a step of forming the first gate electrode (33) and the first conductive layer (39,117) so that the space region (40) having a third length (Sg) of 0.1 µm or more and 0.4 µm or less is formed in the first direction (X).

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a semiconductor layer including a first main surface;
a first region of a first conduction type that is formed at a surface layer portion of the first main surface;
a second region of a first conduction type that is formed at the surface layer portion of the first main surface and is separated from the first region in a first direction;
a channel region of a second conduction type that is formed between the first region and the second region in the surface layer portion of the first main surface;
a first gate electrode that is formed in a vicinity of the first region in the first main surface, faces the channel region, and includes a first side portion and a second side portion on an opposite side of the first side portion in the first direction;
a first gate insulating film formed between the first gate electrode and the semiconductor layer;
a first conductive layer that is formed in a vicinity of the second region in the first main surface, is separated from the first gate electrode across a space region having a predetermined width in the first direction, and includes a third side portion facing the first side portion of the first gate electrode and a fourth side portion on an opposite side of the third side portion;
a first insulating film formed between the first conductive layer and the semiconductor layer; and
a side wall structure that covers the first side portion of the first gate electrode, the third side portion of the first conductive layer, and the first main surface in the space region, and is formed in common to the first gate electrode and the first conductive layer.

2. The semiconductor device of claim 1, further comprising: an element isolation portion that partitions a plurality of memory cell regions is included in the semiconductor layer,
wherein the first gate electrode and the first conductive layer are formed between the first region and the second region in each of the memory cell regions and form a single memory transistor structure in cooperation with the first region and the second region,
wherein the first gate electrode includes a storage gate electrode in which a voltage for accumulating electric charges is applied to the side wall structure, and
wherein the first conductive layer includes a selection gate electrode to which a voltage for selecting each of the memory cell regions as a charge storage target cell is applied.

3. The semiconductor device of claim 1, wherein the side wall structure includes:
a base portion formed on the first main surface;
a first wall portion erected along the first side portion of the first gate electrode from the base portion; and
a second wall portion erected along the third side portion of the first conductive layer from the base portion.

4. The semiconductor device of claim 3, wherein the side wall structure further includes an insulating spacer formed in a space sandwiched between the first wall portion and the second wall portion in the first direction.

5. The semiconductor device of claim 4, wherein the insulating spacer includes a silicon oxide film.

6. The semiconductor device of claim 1, wherein, in the first direction, the first gate electrode has a first length, and the first conductive layer has a second length different from the first length.

7. The semiconductor device of claim 6, wherein the first length is larger than the second length.

8. The semiconductor device of claim 7, wherein the first length is 0.4 µm or more and 1 µm or less, and the second length is 0.1 µm or more and 0.4 µm or less.

9. The semiconductor device of claim 1, wherein, in the first direction, a third length of the space region is 0.1 µm or more and 0.2 µm or less.

10. The semiconductor device of claim 1, wherein the side wall structure includes:
a lower layer film in contact with the first side portion, the third side portion, and the first main surface; and
an upper layer film that is laminated on the lower layer film and contains an insulating material different from an insulating material of the lower layer film.

11. The semiconductor device of claim 10, wherein the lower layer film includes a silicon oxide film, and
wherein the upper layer film includes a silicon nitride film.

12. The semiconductor device of claim 10, wherein the upper layer film has a thickness larger than a thickness of the lower layer film.

13. The semiconductor device of claim 1, further comprising: a first low-concentration impurity region that is formed in a self-aligned manner with respect to the second side portion of the first gate electrode between the first region and the channel region and has an impurity concentration lower than an impurity concentration of the first region.

14. The semiconductor device of claim 1, further comprising: a second low-concentration impurity region that is formed in a self-aligned manner with respect to the fourth side portion of the first conductive layer between the second region and the channel region and has an impurity concentration lower than an impurity concentration of the second region.

15. The semiconductor device of claim 1, further comprising: a coating insulating film that integrally covers a portion of the first region, the first gate electrode, the first conductive layer, and a portion of the second region.

16. The semiconductor device of claim 15, wherein the semiconductor layer includes a Si semiconductor layer, and
wherein the semiconductor device further comprises a silicide film formed in a portion exposed from the coating insulating film, in the first region and the second region.

17. The semiconductor device of claim 1, wherein the first gate electrode and the first conductive layer include a polysilicon layer.

18. The semiconductor device of claim 1, wherein the side wall structure includes an integrated side wall structure that integrally covers the first side portion of the first gate electrode, the third side portion of the first conductive layer, and the first main surface in the space region.

19. A method of manufacturing a semiconductor device, comprising:
forming a first gate electrode and a first conductive layer on a first main surface of a semiconductor layer including the first main surface, wherein the first gate electrode and the first conductive layer separate a space region having a predetermined width in a first direction, the first gate electrode includes a first side portion and a second side portion on an opposite side of the first side portion in the first direction, and the first conductive layer includes a third side portion facing the first side portion of the first gate electrode and a fourth side portion on an opposite side of the third side portion;
forming a first base insulating film at the first main surface to integrally cover the first gate electrode, the space region, and the first conductive layer, wherein the first base insulating film includes a first portion on upper surfaces of the first gate electrode and the first conductive layer and includes a second portion in the space region;
forming a second base insulating film on the first base insulating film to integrally cover the first gate electrode, the space region, and the first conductive layer, wherein the second base insulating film includes a first portion having a first thickness on the first portion of the first base insulating film, and the space region includes a second portion having a second thickness larger than the first thickness;
selectively removing the first portion of the second base insulating film and the first portion of the first base insulating film by etch-back to expose the upper surfaces of the first gate electrode and the first conductive layer, wherein the first side portion of the first gate electrode, the third side portion of the first conductive layer, and the first main surface in the space region are integrally covered by the second portion of the first base insulating film and the second portion of the second base insulating film to form an integrated side wall structure common to the first gate electrode and the first conductive layer;
forming a first region of a first conduction type in a vicinity of the second side portion of the first gate electrode in a surface layer portion of the first main surface; and
forming a second region of a first conduction type in a vicinity of the fourth side portion of the first conductive layer in the surface layer portion of the first main surface.

20. The method of claim 19, wherein the forming the first gate electrode and the first conductive layer includes forming the first gate electrode having a first length in the first direction and the first conductive layer having a second length different from the first length.

21. The method of claim 19, wherein the forming the first gate electrode and the first conductive layer includes forming the first gate electrode and the first conductive layer so that the space region having a third length of 0.1 µm or more and 0.4 µm or less is formed in the first direction.
